(19) United States
(12) Patent Application Publication
(10) Pub. No.: US 2015/0029374 A1
(43) Pub. Date: Jan. 29, 2015

(54) IMAGE SENSOR, MANUFACTURING APPARATUS AND METHOD, AND IMAGING APPARATUS

(71) Applicant: Sony Corporation, Tokyo (JP)

(72) Inventor: Yoshiaki Kitano, Kumamoto (JP)

(73) Assignee: SONY CORPORATION, Tokyo (JP)

(21) Appl. No.: 14/372,501

(22) PCT Filed: Feb. 1, 2013
(86) PCT No.: PCT/JP2013/052328

§ 371 Date: Jul. 16, 2014

(30) Foreign Application Priority Data
Feb. 10, 2012 (JP) 2012-026933

(51) Int. Cl. H01L 27/146; H04N 5/378; H04N 5/374

(52) U.S. Cl. CPC H01L 27/14643; H04N 5/374; H04N 5/378; H01L 27/14689; H01L 27/14616
USPC 348/308; 257/292; 438/59; 29/25.01

(57) ABSTRACT

The present disclosure relates to an image sensor, a manufacturing apparatus and method, and an imaging apparatus that are capable of further enlarging a charge accumulation region. In the image sensor of this disclosure, a channel portion of a readout transistor that constitutes a pixel and a floating diffusion are formed so as to be overlaid with each other at least partly. For example, the channel portion and the floating diffusion are formed in the form of a column on a surface of a photodiode that constitutes the pixel. This disclosure can be applied to the manufacturing apparatus and method, and the imaging apparatus, in addition to the image sensor.

### TECHNICAL FIELD

The present disclosure relates to an image sensor, a manufacturing apparatus and method, and an imaging apparatus, specifically to an image sensor, a manufacturing apparatus and method, and an imaging apparatus that are capable of further enlarging a charge accumulation region.

### BACKGROUND ART

In the past, in a Complementary Metal Oxide Semiconductor (CMOS) image sensor, a charge accumulation region, a transfer gate, a floating diffusion, and transistors that conduct amplification, selection, reset, or the like are formed in a pixel region.

For example, a method has been thought that causes signal charge accumulated in a photodiode to be read out from a periphery of the transfer gate to the floating diffusion by disposing the floating diffusion surrounded by the gate electrode within a photodiode region (refer to a Patent Literature 1, for example).

### CITATION LIST

### Patent Literature

Patent Literature 1: JP 2011-049446A

### SUMMARY OF INVENTION

### Technical Problem

However, in a case in the past, because each of the above-described constituents is disposed in a planar state in the pixel region, the charge accumulation region becomes at a maximum a part that is not the other constituents in the pixel region, and thus cannot be enlarged beyond that. Namely, it is concerned that a size of the charge accumulation region may be limited by the other constituents.

A size of the charge accumulation region influences an amount of accumulated charge Qs of the pixel. And the amount of accumulated charge Qs places an important influence on an image quality. Namely, in a case in the past, a maximum value of an amount of accumulated charge Qs in each pixel is limited by the constituents such as the transfer gate, the floating diffusion, and the transistors that conduct amplification, selection, reset, or the like, which may lead to a concern of a degraded image quality.

The present disclosure has been made in view of such a circumstance, and is directed to further enlarge a charge accumulation region and increase an amount of accumulated charge, thereby to suppress image quality degradation.

### Solution to Problem

According to an aspect of the present disclosure, there is provided an image sensor including a channel portion of a readout transistor that constitutes a pixel, and a floating diffusion. The channel portion and the floating diffusion are formed so as to be overlaid with each other at least partly.

The channel portion and the floating diffusion may be partly or entirely exposed outside a photodiode that constitutes the pixel.

The channel portion and the floating diffusion may be formed in a form of a column on a surface of a photodiode that constitutes the pixel.

The channel portion and the floating diffusion may be formed within a region of a photodiode that constitutes a single pixel.

The channel portion and the floating diffusion may be shared by a plurality of pixels.

A gate electrode of the readout transistor may be formed so as to partly or entirely surround side surfaces of the channel portion and the floating diffusion.

The image sensor may further include a first chip in which the readout transistor, the floating diffusion, and a photodiode that constitutes the pixel are formed, and a second chip in which a transistor for amplification, a transistor for selection, and a transistor for reset that constitute the pixel are formed. The first chip and the second chip may be overlaid and combined with each other.

The first chip and the second chip may be combined so that a wiring within the pixel of the first chip and a wiring of the second chip are attached, with respect to corresponding circuits for every pixel or for every plurality of pixels.

A third chip in which a logic circuit including a transistor of an output section or an input section of the pixel may be further overlaid and combined with the second chip combined with the first chip.

A P− layer of a channel portion of at least one of a transistor for amplification, a transistor for selection, and a transistor for reset that constitute the pixel may be formed so as to be piled on a P+ layer.

According to another aspect of the present disclosure, there is provided a manufacturing apparatus that manufactures an image sensor, the manufacturing apparatus including a channel forming unit that forms a channel portion of a readout transistor that constitutes a pixel, and a floating diffusion forming unit that forms a floating diffusion so that the floating diffusion and the channel portion formed by the channel forming unit is overlaid with each other at least partly.

The manufacturing apparatus further includes a photodiode forming unit that forms a photodiode. The channel forming unit may form the channel portion on a surface of the photodiode formed by the photodiode forming unit. The floating diffusion forming unit may form the floating diffusion so that the floating diffusion is overlaid to the channel portion formed on the surface of the photodiode.

The floating diffusion forming unit may form the floating diffusion over the surface of the photodiode formed by the photodiode forming unit. The channel forming unit may form the channel portion inside the photodiode so that the channel portion is overlaid to the floating diffusion formed by the floating diffusion forming unit.

The manufacturing apparatus may further include a transistor forming unit that forms at least one of a transistor for amplification, a transistor for selection, and a transistor for reset that constitute the pixel is formed so that a P− layer of each channel portion is piled on a P+ layer.

The manufacturing apparatus may further include a manufacturing unit that manufactures a second chip in which a transistor for amplification, a transistor for selection, and a transistor for reset that constitute the pixel are formed, as a chip different from a first chip in which the readout transistor and the floating diffusion are formed, and a combining unit that overlays and combines the second chip manufactured by the manufacturing unit on the first chip.

The combining unit may combine the first chip and the second chip by attaching a wiring within the pixel of the first chip and a wiring of the second chip with respect to corresponding circuits for every pixel or for every plurality of pixels.

The manufacturing apparatus may further include a third chip manufacturing unit that manufactures a third chip in which a logic circuit including a transistor for an input section or an output section of the pixel is formed, and a third chip combining unit that combines the third chip manufactured by the third chip manufacturing unit with the second chip combined with the first chip by the combining unit.

According to another aspect of the present disclosure, there is provided a manufacturing method that manufactures an image sensor, the manufacturing method including forming a channel portion of a readout transistor that constitutes a pixel of the image sensor, by a channel forming unit, and forming a floating diffusion so that the floating diffusion and the formed channel portion is overlaid with each other at least partly, by a floating diffusion forming unit.

According to still another aspect of the present disclosure, there is provided an imaging apparatus including an image sensor formed so that a channel portion of a readout transistor that constitutes a pixel and a floating diffusion are overlaid with each other at least partly, and an image processing unit that executes image processing on an image of an object obtained in the image sensor.

The floating diffusion and the channel portion of the image sensor may be formed in a form of a column on a surface of a photodiode that constitutes the pixel.

According to one aspect of the present disclosure, the channel part of the readout transistor that constitutes the pixel and the floating diffusion are formed to be overlaid with each other at least partly.

According to another aspect of the present disclosure, the channel portion of the readout transistor that constitutes the pixel is formed, and the floating diffusion is formed to be overlaid at least partly with respect to the channel portion.

According to still another aspect of the present disclosure, the channel part of the readout transistor that constitutes the pixel and the floating diffusion are formed to be overlaid with each other at least partly in the image sensor, and the image of the object obtained in the image sensor is processed.

### Advantageous Effects of Invention

According to this disclosure, specifically, a charge accumulation region can be further enlarged.

### BRIEF DESCRIPTION OF DRAWINGS

FIG. 1 is a cross-sectional view illustrating an example of a principal configuration of an image sensor to which the present technique is applied.

FIG. 2 is a block diagram illustrating an example of a principal configuration of a manufacturing apparatus that manufactures the image sensor.

FIG. 3 is a flowchart explaining an example of flow of manufacturing process.

FIG. 4 is a view illustrating examples of manufacturing states.

FIG. 5 is a view illustrating examples of manufacturing states, continuing from FIG. 4.

FIG. 6 is a view explaining examples of shapes of a floating diffusion.

FIG. 7 is a view explaining an example where a floating diffusion is shared by plural pixels.

FIG. 8 is a cross-sectional view explaining an example of a principal configuration of an image sensor to which the present technique is applied.

FIG. 9 is a view explaining examples of configurations of pixel regions.

FIG. 10 is a block diagram illustrating an example of a principal configuration of a manufacturing apparatus that manufactures the image sensor.

FIG. 11 is a flowchart explaining an example of flow of manufacturing process.

FIG. 12 is a view illustrating examples of manufacturing states.

FIG. 13 is a view illustrating examples of manufacturing states, continuing from FIG. 12.

FIG. 14 is a cross-sectional view explaining an example of a principal configuration of an image sensor to which the present technique is applied.

FIG. 15 is a block diagram illustrating an example of a principal configuration of a manufacturing apparatus that manufactures the image sensor.

FIG. 16 is a flowchart explaining an example of flow of manufacturing process.

FIG. 17 is a view illustrating examples of manufacturing states.

FIG. 18 is a view illustrating examples of manufacturing states, continuing from FIG. 17.

FIG. 19 is a cross-sectional view explaining an example of a principal configuration of an image sensor to which the present technique is applied.

FIG. 20 is a perspective view explaining an example of a principal configuration of the image sensor to which the present technique is applied.

FIG. 21 is a plan view explaining an example of a principal configuration of an image sensor to which the present technique is applied.

FIG. 22 is a block diagram illustrating an example of a principal configuration of a manufacturing apparatus that manufactures the image sensor to which the present technique is applied.

FIG. 23 is a flowchart explaining an example of flow of manufacturing process.

FIG. 24 is a view illustrating examples of manufacturing states.

FIG. 25 is a view illustrating examples of manufacturing states, continuing from FIG. 24.

FIG. 26 is a block diagram illustrating an example of a principal configuration of an imaging apparatus to which the present technique is applied.

### DESCRIPTION OF EMBODIMENTS

In the following, embodiments for practicing the present technique (referred to as embodiments hereinafter) will be explained. This explanation will be made in the following order.

1. First Embodiment (Image sensor, Manufacturing Apparatus, Manufacturing Method)

2. Second Embodiment (Image sensor, Manufacturing Apparatus, Manufacturing Method)

3. Third Embodiment (Image sensor, Manufacturing Apparatus, Manufacturing Method)

4. Fourth Embodiment (Image sensor, Manufacturing Apparatus, Manufacturing Method)

5. Fifth Embodiment (Imaging Apparatus)

### 1. First Embodiment

### Image Sensor

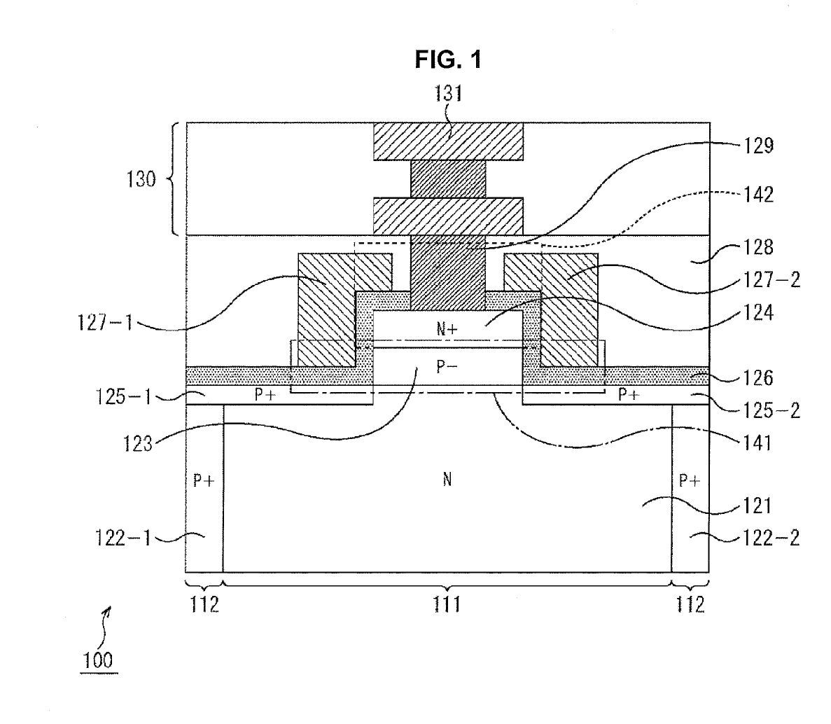

FIG. 1 is a cross-sectional view illustrating an example of a principal configuration, regarding a part of an image sensor to which the present technique is applied. An image sensor 100 illustrated in FIG. 1 performs photoelectric conversion on the light incoming from the lower side of the drawing, and thus outputs an image of an object, as an electric signal.

FIG. 1 illustrates a configuration corresponding to a single pixel of the image sensor 100. As illustrated in FIG. 1, a photodiode 111 constituting the single pixel is partitioned by a pixel isolation region 112. In addition, in the upper side of the photodiode 111 in the drawing, a transfer gate (TG) 141 (a readout transistor) indicated by a chain line and a floating diffusion (FD) 142 indicated by a dot line are formed. Namely, in a plan view seen from the upper side or the lower side of FIG. 1, the pixel isolation region 112 is formed so as to surround a region of the photodiode 111, and the TG 141 and the FD 142 are formed inside the region of the photodiode 111.

As illustrated in FIG. 1, an N region 121, which is a photoelectric conversion and charge accumulation region of the photodiode 111, is partitioned by a pixel isolation region 112 composed of a P+ region 122 (a P+ region 122-1 and a P+region 122-2). In practice, the P+ region 122-1 and the P+ region 122-2 may constitute a connected single region. When there is no need to distinctively refer to, the P+ region 122-1 and the P+ region 122-2 may be simply referred to as the P+ region 122.

In addition, in the upper side of a part of the N region 121 in the drawing, a P− layer 123, which is a channel portion of the TG 141, is formed. Moreover, in the upper side of the P− layer 123 in the drawing, an N+ layer 124 constituting the FD 142 is formed.

In a part where the P− layer 123 is not layered in the N region 121 and in the upper side of the P+ region 122 in the drawing, a P+ layer 125 (a P+ layer 125-1 and a P+ layer 125-2) of a high impurity concentration is formed. In practice, the P+ region 125-1 and the P+ region 125-2 may constitute a connected single region. When there is no need to distinctively refer to, the P+ region 125-1 and the P+ region 125-2 may be simply referred to as the P+ region 125.

Furthermore, as illustrated in FIG. 1, in the upper sides of the P+ layer 125 and the N+ layer 124 in the drawing, an insulating film 126 made of SiO2, a High-k material, or the like is formed.

In addition, a gate of the TG 141 is formed so as to cover (or surround a perimeter of) the channel portion of the TG 141. Namely, as illustrated in FIG. 1, a gate electrode 127 (a gate electrode 127-1 and a gate electrode 127-2) made of poly-silicon (poly Si) or the like is formed so as to cover P− layer 123 from the upper side of the insulating film 126 in the drawing. In practice, the gate electrode 127-1 and the gate electrode 127-2 may constitute a connected single region. When there is no need to distinctively refer to, the gate electrode 127-1 and the gate electrode 127-2 may be simply referred to as the gate electrode 127.

Moreover, in the upper sides of the insulating layer 126 and the gate electrode 127 in the drawing, an interlayer insulating film 128 made of SiO2 or the like is formed. In addition, in the upper side of the interlayer insulating film 128, there is formed a wiring layer 130 with a wiring 131 formed. In the upper side of the N+ layer 124 of the FD 142, a contact 129 that goes through the insulating film 126 and the interlayer insulating film 128 is formed. The contact 129 connects the N+ layer 124 of the FD 142 with the wiring 131. The wiring 131 is made of, for example, an electrically conductive metal (Metal) such as copper (Cu) and aluminum, and connects the FD 142 (the N+ layer 124) to another element through the contact 129.

As above, in the image sensor 100, the FD 142 (the N+Layer 124) is formed (in the form of a column) so as to be overlaid on the channel portion (the P− layer 123) of the TG 141. (The FD 142 (the N+ layer 124) and the channel portion (the P− layer 123) of the TG 141 are in the form of a layered structure).

With this, when transferring charge accumulated in the N region 121 of the photodiode 111 to the FD 142, the charge can be transferred in a layered direction (in an up-and-down direction in the drawing), which makes it possible to form the N region 121 in the lower side of the FD 142 (the N+ layer 124) (the channel portion (the P− layer 123) of the TG 141). In other words, in the image sensor 100, the photodiode 111 (the N region 121), the channel portion (the P− layer 123) of the TG 141, and the FD 142 (the N+ layer 124) are formed so as to be mutually overlaid.

Therefore, the N region 121, which is the charge accumulation region, can be enlarged and thus increase an amount of the accumulated charge Qs, compared with a case where a TG and a photodiode are formed in a perimeter of the FD as described in the Patent Literature 1. Accordingly, the image sensor 100 can improve an image quality of a captured image (or output a captured image with higher quality).

### [Manufacturing Apparatus]

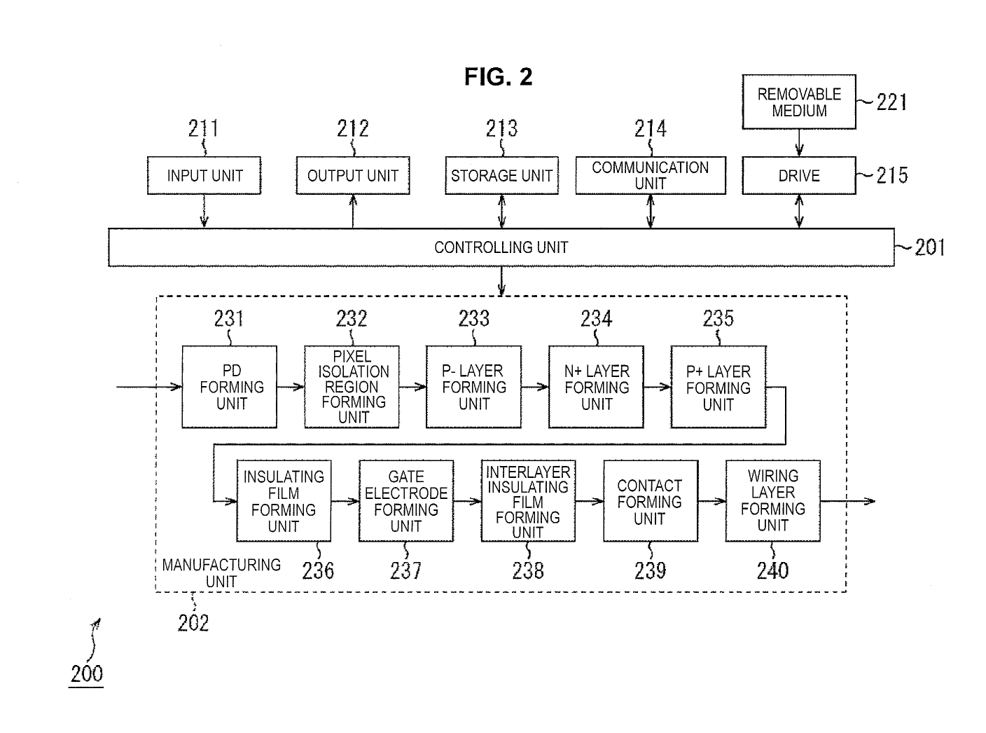

FIG. 2 is a block diagram illustrating an example of a principal configuration of a manufacturing apparatus for manufacturing the image sensor to which the present technique is applied. A manufacturing apparatus 200 illustrated in FIG. 2 is an apparatus that manufactures the image sensor 100 (FIG. 1) to which the present technique is applied. Namely, the manufacturing apparatus 200 manufactures the image sensor where the FD 142 (the N+ layer 124) and the channel portion (the P− layer 123) of the TG 141 are formed so as to be overlaid with each other at least partly.

The manufacturing apparatus 200 has a controlling unit 201 and a manufacturing unit 202.

The controlling unit 201 has, for example, a Central Processing Unit (CPU), a Read Only Memory (ROM), a Random Access Memory (RAM), and the like, controls each unit of the manufacturing unit 202, and conducts controlling processes regarding manufacture of the image sensor 100. For example, the CPU of the controlling unit 201 performs various processes in accordance with programs stored in the ROM. In addition, the CPU performs various processes in accordance with programs loaded from a storage unit 213 to the RAM. In the RAM, also data to be necessary at the time for the CPU to perform various processes are arbitrarily stored.

The manufacturing apparatus 200 has an input unit 211, an output unit 212, the storage unit 213, a communication unit 214, and a drive 215.

The input unit 211 is composed of a keyboard, a mouse, a touch panel, an outside input terminal, or the like. Inputs of user instructions or information from the outside are received and supplied to the controlling unit 201 by the input unit 211. The output unit 212 is composed of a display such as a Cathode Ray Tube (CRT) display and a Liquid Crystal Display (LCD), a speaker, an outside output terminal, and the like, and outputs various pieces of information supplied from the controlling unit 201 as an image, a phonetic sound, an analog signal, or digital data.

The storage unit 213 is composed of a flash memory such as a Solid State Drive (SSD), or a Hard Disk Drive, stores the information supplied from the controlling unit 201, and read outs and supplies the stored information in accordance with a request from the controlling unit 201.

The communication unit 214 is composed of, for example, an interface or a modem for a wired Local Area Network (LAN) or a wireless LAN, and conducts communication processes with outside apparatuses through a network including the Internet. For example, the communication unit 214 sends the information supplied from the controlling unit 201 to a communication party, and supplies information received from the communication party to the controlling unit 201.

The drive 215 is connected to the controlling unit 201, as may be necessary. And a removable media 221 such as a magnetic disk, an optical disk, a magnetooptical disk, and a semiconductor memory are arbitrarily loaded into the drive 215. Then, a computer program read out from the removable media 221 through the drive 215 is installed into the storage unit 213, as may be necessary.

The manufacturing unit 202 is controlled by the controlling unit 201, and conducts processes regarding manufacture of the image sensor 100 to which the present technique is applied. As illustrated in FIG. 2, the manufacturing unit 202 has a photodiode (PD) forming unit 231, a pixel isolation region forming unit 232, a P− layer forming unit 233, an N+ layer forming unit 234, a P+ layer forming unit 235, an insulating film forming unit 236, a gate electrode forming unit 237, an interlayer insulating film forming unit 238, a contact forming unit 239, and a wiring layer forming unit 240.

### [Flow of Manufacturing Process]

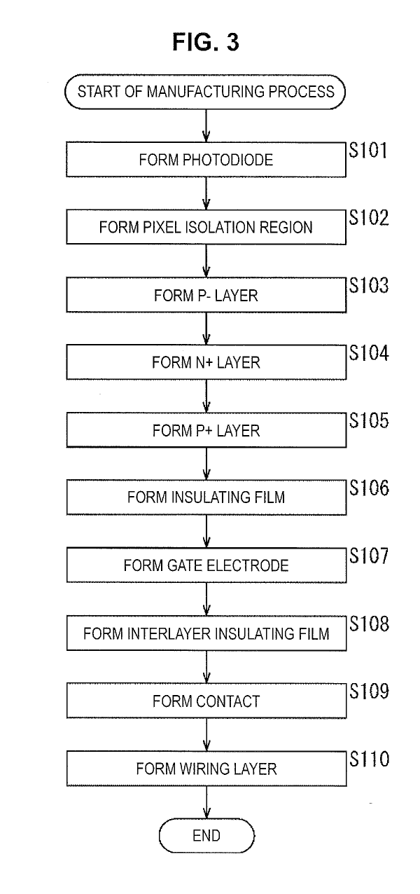

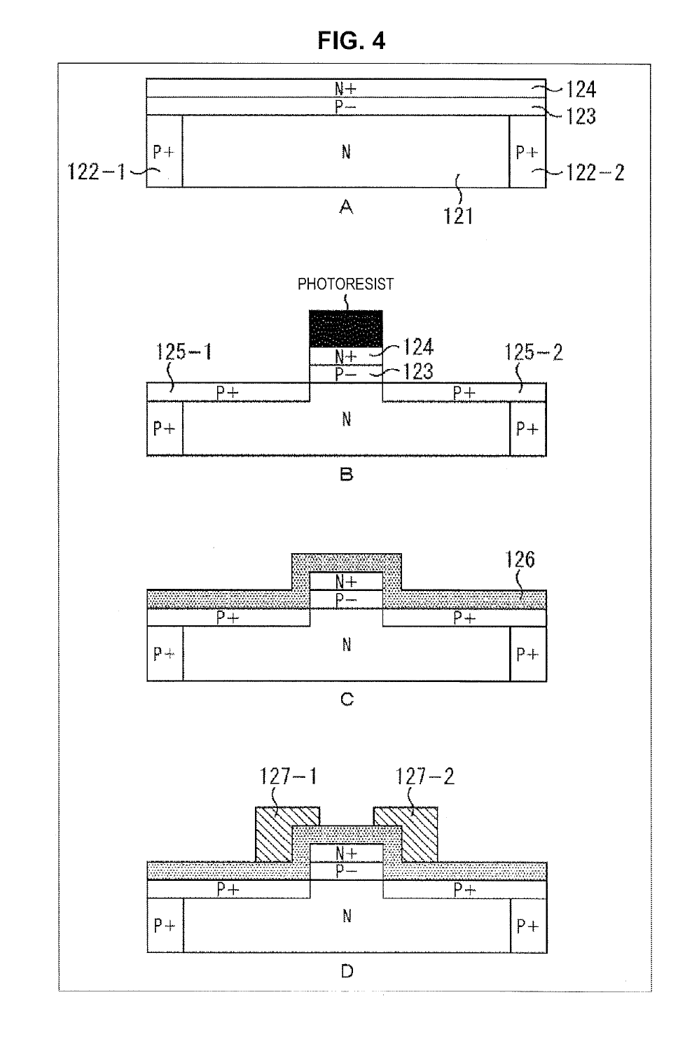

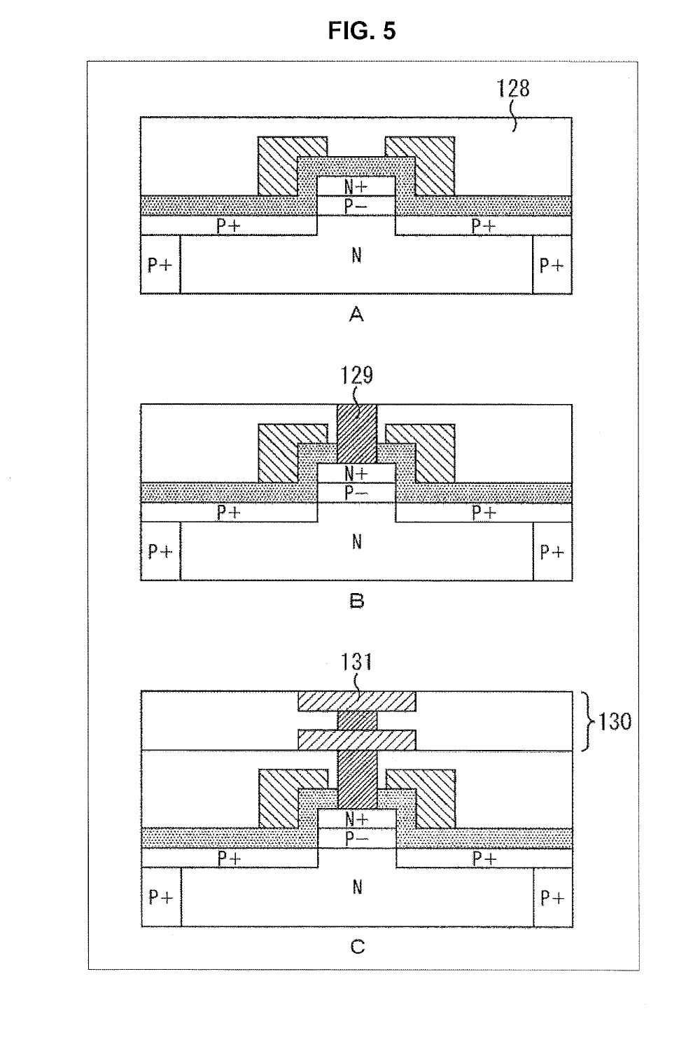

With reference to a flowchart of FIG. 3, an example of flow of manufacturing process performed by the manufacturing unit 202 is explained. The explanation is made with reference to FIG. 4 and FIG. 5, as may be necessary.

When the manufacturing process is started, the PD forming unit 231 is controlled by the controlling unit 201, and forms the N region 121 (the photodiode 111), which is an N-type photoelectric conversion and charge accumulation region, on an upper surface of a silicon (Si) substrate supplied from the outside, at Step S101.

At Step S102, the pixel isolation region forming unit 232 is controlled by the controlling unit 201, and forms the P+ region 122 (the pixel isolation region 112) so that the P+ region 122 surrounds the photodiode 111 of a device that has been supplied from the PD forming unit 231.

At Step S103, the P− layer forming unit 233 is controlled by the controlling unit 201, and forms the P− layer 123, which corresponds to the channel portion of the TG 141, on the upper surface of the photodiode 111 (the N region 121) and the pixel isolation region 112 (the P+ region 12) of a device that has been supplied from the pixel isolation region forming unit 232.

At Step S104, the N+ layer forming unit 234 is controlled by the controlling unit 201, and forms the N+ layer 124 of the FD 142 on the upper surface of the P− layer 123 of a device that has been supplied from the P− layer forming unit 233 (FIG. 4A).

At Step S105, the P+ layer forming unit 235 is controlled by the controlling unit 201, removes a part of the P− layer 123 and the N+ layer 124 of a device that has been supplied from the N+ layer forming unit 234, and forms the P+ layer 125 on the upper surfaces of the N region 121 and the P+ region 122. More specifically, the P+ layer forming unit 235 applies a photoresist on the upper surface of the N+ layer 124, and employs a mask and a photolithography technique, thereby to form a photoresist opening region, except parts that turn out to be the channel portion of the TG 141 and the FD 142. Then, the P+ layer forming unit 235 removes the P− layer 123 and the N+ layer 124 in the photoresist opening region by a method such as dry etching. Namely, the P+ layer forming unit 235 leaves a part of the P− layer 123 and the N+ layer 124, the part turning out to be the FD 142 and the channel portion of the TG 141, and removes the other parts of the P− layer 123 and the N+ layer 124. With this, the P− layer 123 and the N+ layer 124, which are layered in the form of a column, are formed. Then, the P+ layer forming unit 235 forms the P+ layer 125 in the photoresist opening region (parts except the P− layer 123 and the N+ layer 124 that are layered in the form of a column) (FIG. 4B), and removes the photoresist left on the upper surface of the N+ layer 124 by ashing.

At Step S106, the insulating film forming part 236 is controlled by the controlling unit 201, and forms the insulating film 126 on the upper surfaces of the N+ layer 124 and the P+ layer 125 of a device that has been supplied from the P+ layer forming unit 235 (FIG. 4C).

At Step S107, the gate electrode forming unit 237 is controlled by the controlling unit 201, and forms the gate electrode 127 so that the gate electrode 127 surrounds (covers) the perimeter of the P− layer 123 and the N+ layer 124 that are formed in the form of a column, from the above of the insulating film 126 of a device that has been supplied from the insulating film forming unit 236 (FIG. 4D). More specifically, the gate electrode forming unit 237 forms a film of a gate electrode material such as poly silicon from the above of the insulating film 126, conducts applying a photoresist, forming a photoresist opening due to a mask and a photolithography technique, and dry-etching, thereby to process the film and to form the gate electrode 127.

At Step S108, the interlayer insulating film forming unit 238 is controlled by the controlling unit 201, and forms a film of the interlayer insulating film 128 on the upper surface of a device that has been supplied from the gate electrode forming unit 237 (or of the insulating film 126 and the gate electrode 127) (FIG. 5A).

At Step S109, the contact forming unit 239 is controlled by the controlling unit 201, and forms the contact 129 so that the contact 129 goes through the interlayer insulating film 128 and the insulating film 126 until the N+ layer 124 from the upper surface of a device that has been supplied from the interlayer insulating film forming unit 238 (FIG. 5B).

At Step S110, the wiring layer forming unit 240 is controlled by the controlling unit 201, and forms the wiring layer 130 on the upper surface of a device that has been supplied from the contact forming unit 239 (FIG. 5C).

When the wiring layer is formed, the manufacturing unit 202 supplies the image sensor 100 manufactured as above to outside, and completes the manufacturing process.

As above, the manufacturing apparatus 200 is capable of manufacturing the image sensor 100 with ease, through basically the same number of processes as that of a case where an image sensor in the past is manufactured.

Incidentally, an order of the processes described above may be arbitrarily changed, as long as no inconsistency arises.

### [Additional Statement]

While FIG. 1 illustrates an example of a configuration corresponding to a single pixel as the image sensor 100, the image sensor 100 may have the arbitrary number of pixels, in practice. When the image sensor 100 has plural pixels, at least one of the pixels may have the configuration illustrated in FIG. 1.

In addition, while in FIG. 1 the gate electrode 127 is illustrated so as to cover an upper portion of the FD 142 in the drawing, the gate electrode 127 may be disposed at least in a range where a voltage can be applied to the P− layer 123, which is the channel portion of the TG 141, and the gate electrode 127 is arbitrary positioned as long as the position is within such a range. For example, the gate electrode 127 may be formed on the upper surface of the insulating film 126 so as to surround a part or entirety of the side surface of the P− layer 123 or the N+ layer 124, or to surround a part or entirety of the side surfaces of the P− layer 123 and the N+ layer 124. Moreover, the gate electrode 127 does not necessarily surround the entire side surfaces of the P− layer 123 and the N+ layer 124.

Incidentally, while the P− layer 123 and the N+ layer 124 are formed so as to be overlaid in FIG. 1, the channel portion of the TG 141 (the P− layer 123) may be piled with a part of the FD 142 (the N+ layer 124). In addition, the FD 142 (the N+ layer 124) may be piled with a part of the channel portion of the TG 141 (the P− layer 123). Moreover, a part of the FD 142 (the N+ layer 124) may be piled with a part of the channel portion of the TG 141 (the P− layer 123). Namely, the channel portion of the TG 141 (the P− layer 123) and the FD 142 (the N+ layer 124) may be overlaid with each other at least partly. For example, the TG 141 and the FD 142 may be displaced (may exist in different positions) with each other in a plan view seen from the upper side or the lower side of FIG. 1.

Respective shapes of the TG 141 and the FD 142 are arbitrary, and may be different from each other. In addition, in a plan view seen from the upper side or the lower side of FIG. 1, respective positions of the TG 141 and the FD 142 are arbitrary, as long as a overlaid part of the channel portion (the P− layer 123) of the TG 141 and the FD 142 (the N+ layer 124) is within the region of the photodiode 111.

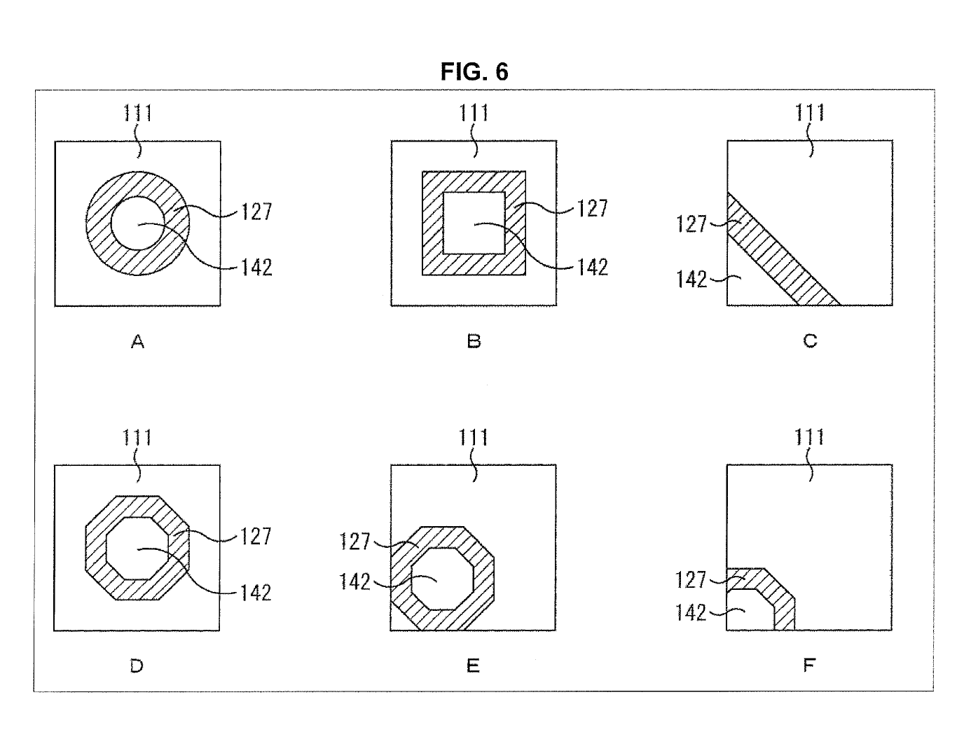

For example, the TG 141 and the FD 142 may be formed in the form of a substantial circle (or a substantial circular column) in a substantial center of the region of the photodiode 111 in a plan view seen from the upper side or the lower side of FIG. 1, as illustrated in FIG. 6A. In addition, for example, the TG 141 and the FD 142 may be formed in the form of a rectangle (or a rectangular column) in a substantial center of the region of the photodiode 111 in a plan view seen from the upper side or the lower side of FIG. 1, as illustrated in FIG. 6B. Moreover, for example, the TG 141 and the FD 142 may be formed in the form of a triangle (or a triangular column) in an edge part of the region of the photodiode 111 in a plan view seen from the upper side or the lower side of FIG. 1, as illustrated in FIG. 6C.

In addition, for example, the TG 141 and the FD 142 may be formed in the form of a polygon such as an octagon (or a polygonal column) in a substantial center of the region of the photodiode 111 in a plan view seen from the upper side or the lower side of FIG. 1, as illustrated in FIG. 6D. Moreover, the TG 141 and the FD 142 of an octagonal shape may be formed in an edge part of the region of the photodiode 111 in a plan view seen from the upper side or the lower side of FIG. 1, as illustrated in FIG. 6E.

Furthermore, for example, a part of the TG 141 and the FD 142 that are in the form of an octagon may be formed in an edge part of the region of the photodiode 111 in a plan view seen from the upper side or the lower side of FIG. 1, as illustrated in FIG. 6F. Namely, the gate electrode 127 does not necessarily surround the entire perimeter of the FD 142, as with the examples of FIG. 6C and FIG. 6F.

However, by providing the TG 141 and the FD 142 in a substantial center of the region of the photodiode 111 as with the examples of FIGS. 6A, 6B, and 6D, a signal charge can be easily read out, thereby to reduce a residual image, because the longest one of readout distances from the photodiode 111 through the FD 142 is shortened.

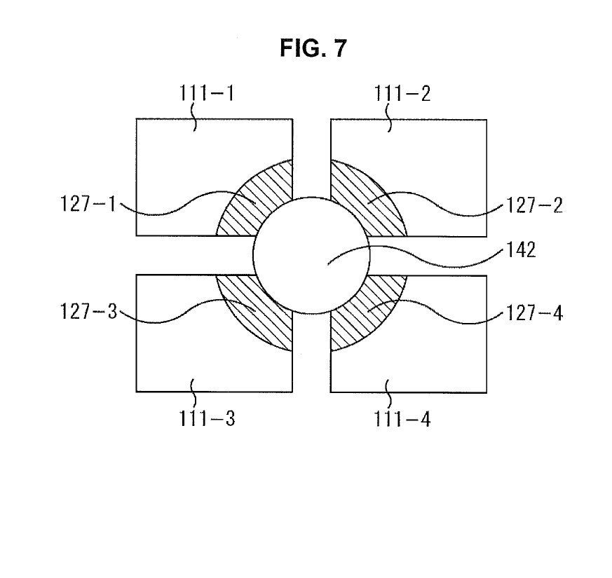

Incidentally, the FD 142 may be shared by plural pixels, as with an example of FIG. 7, for example. In this case, the TG 141 corresponding to the FD 142 needs to be prepared respectively for the pixels that share the TG 141. In the case of the example of FIG. 7, a single FD 142 is shared by four pixels. Therefore, four of the photodiodes 111 and the TG 141 are provided for the single FD 142.

### 2. Second Embodiment

### Image Sensor

Incidentally, although omitted in FIG. 1, the image sensor 100 has logic circuits including a transistor for amplification (an amplifier (Amp)), a transistor for selection (a selector (Sel)), and a transistor for reset (a reset (Rst), or the like for every pixel.

These transistors, which may be formed in any manner though, may be formed in a chip different from a chip having the photodiode 111 illustrated in FIG. 1, and these chips may be layered by attaching the respective wirings (Metal) together, with respect to corresponding circuits for every pixel or for every plural pixels.

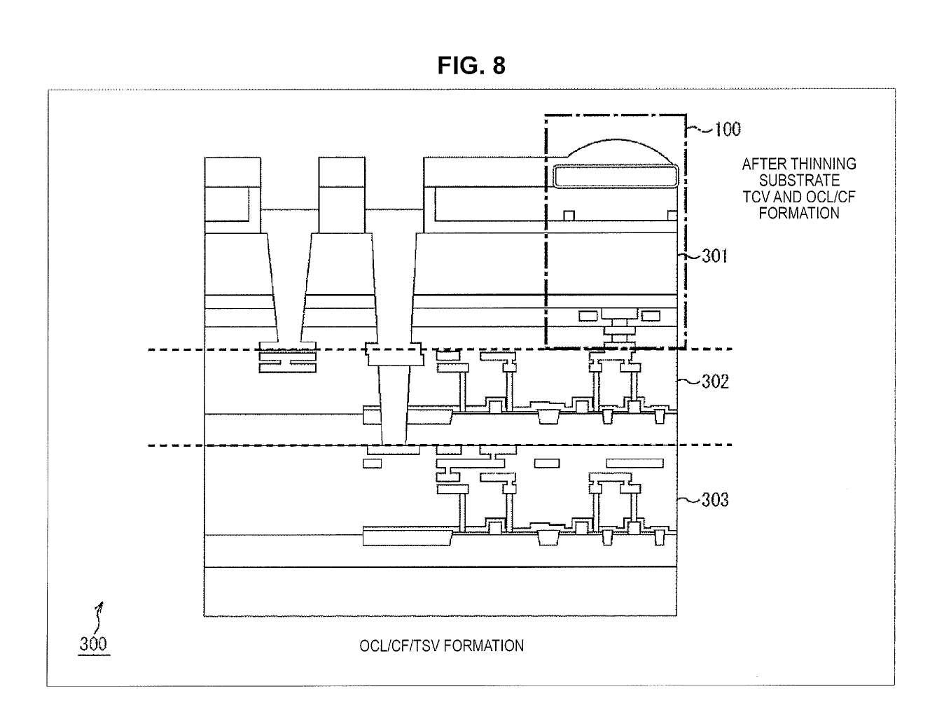

FIG. 8 is a cross-sectional view illustrating an example of a principal configuration of the image sensor in that case. An image sensor 300 illustrated in FIG. 8 performs photoelectric conversion on the light incoming from the upper side of the drawing, and thus outputs an image of an object, as an electric signal.

As illustrated in FIG. 8, the image sensor 300 has a configuration where respective chips of an image sensor chip (Contact Image Sensor (CIS)) 301, a logic circuit chip (Logic 1) 302, and a logic circuit chip (Logic 2) 303 are attached.

A pixel with essentially the same configuration as that in the image sensor 100 is formed in the image sensor chip (CIS) 301. A part indicated by a dashed line in FIG. 8 corresponds to the image sensor 100 (a color filter and a collecting lens are added to the image sensor 100).

In the logic circuit chip (Logic 1) 302, a logic circuit of the transistor for amplification (the amplifier (Amp)), the transistor for selection (the selector (Sel)), and the transistor for reset (the reset (Rst)), and the like for a pixel configuration of the image sensor chip (CIS) 301 is formed.

In the logic circuit chip (Logic 2) 303, another logic circuit including transistors of an input section and an output section for the pixel, or the like is formed.

Respective wirings of the image sensor chip (CIS) 301, the logic circuit chip (Logic 1) 302, and the logic circuit chip (Logic 2) 303 are connected with one another through vias (VIA) or the like. Specifically, the wiring of the image sensor 100 of the image sensor chip (CIS) 301 is attached to the wiring of the logic circuit chip (Logic 2) 302 in the vicinity of the image sensor 100.

Generally, the vias cannot be provided within a pixel. In contrast, by attaching the wiring of the image sensor chip (CIS) 301 and the logic circuit (Logic 1) 302 in a pixel, with respect to corresponding circuits for every pixel or for every plural pixels as described above, a layout of wirings that connect the transistors such as the amplifier (Amp) and the reset (Rst) from the FD 142 is simplified, thereby to improve a degree of freedom in wiring design and to facilitate designing.

In addition, for the same reason, in the case of wiring connections by vias, the wiring that connects the transistors such as the amplifier (Amp) and the reset (Rst) from the FD 142 becomes long, which may lead to reduce conversion efficiency due to wiring capacitance or the like. In contrast, by attaching the wirings of the both chips in a pixel, with respect to corresponding circuits for each pixel or for every plural pixels, as described above, a length of the wiring can be shortened, thereby to suppress reduced conversion efficiency.

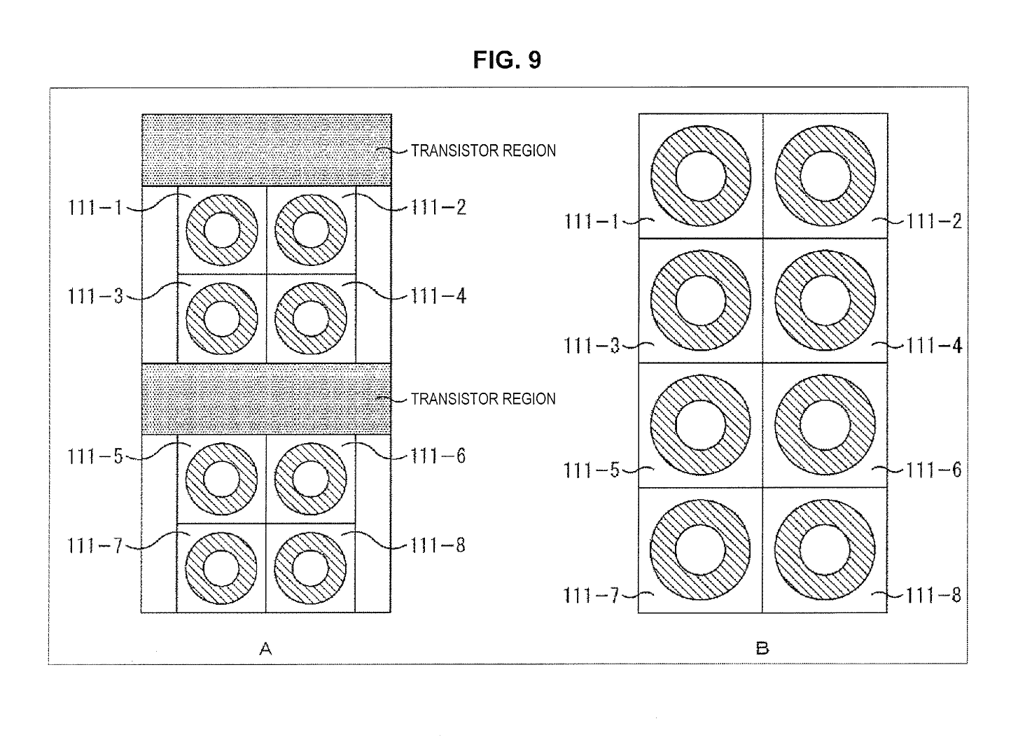

Moreover, in this manner, the transistors for the amplifier, the selector, the reset, and the like can be overlaid to the photodiode 111. Therefore, while transistor regions where those transistors are disposed need to be provided in addition to the region of the photodiode 111 in a case in the past as illustrated in FIG. 9A, the need for such a transistor region can be eliminated as illustrated in FIG. 9B by taking a configuration as illustrated in FIG. 8. Accordingly, the photodiode 111 in each pixel can be enlarged. Namely, an amount of accumulated charge Qs can be increased, thereby to improve image quality of a captured image.

In addition, because the image sensor chip (CIS) 301 and the logic circuit chip (Logic 1) 302 are separately provided, the number of processes for each chip can be reduced, thereby to conduct manufacture of each chip with further ease. Moreover, because only the photodiode 111, the TG 141, and the FD 142 are formed in the image sensor chip (CIS) 301, a thermal treatment can be conducted independently of dynamic characteristics of the transistors (the logic circuits). Therefore, a low noise image sensor with fewer crystalline defects can be realized by the thermal treatment at higher temperatures.

Incidentally, the logic circuit of the logic circuit chip (Logic 2) 303 may be configured in the logic circuit chip (Logic 1) 302. However, by taking a layered structure as with FIG. 8, a chip size can be further reduced.

### [Manufacturing Apparatus]

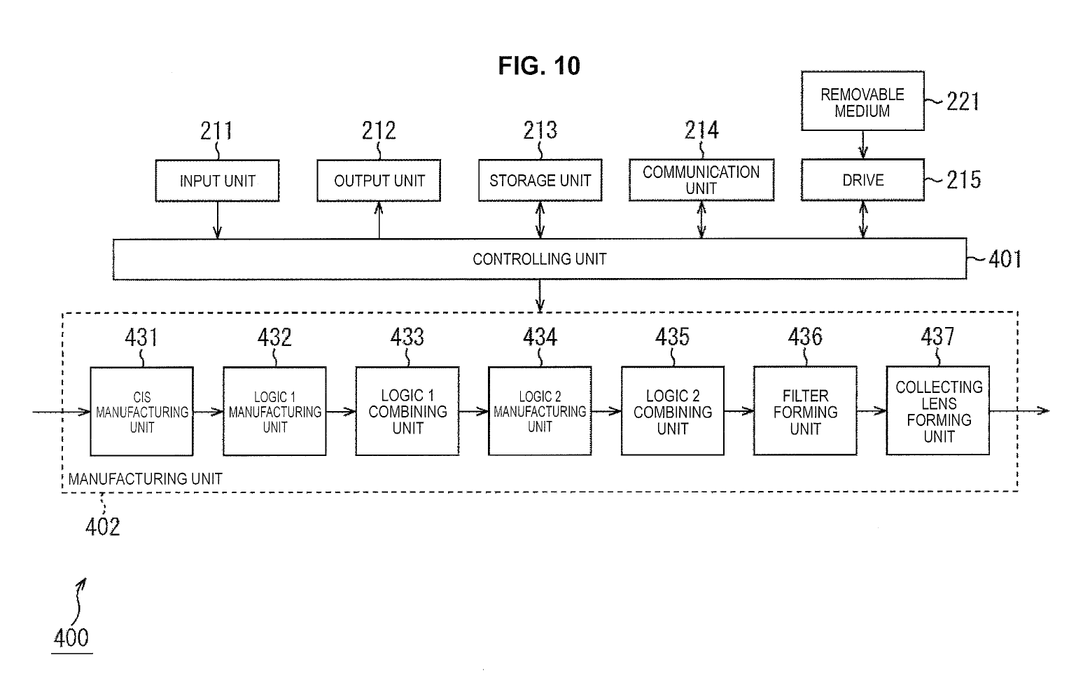

FIG. 10 is a block diagram illustrating an example of a principal configuration of a manufacturing apparatus for manufacturing the image sensor to which the present technique is applied. A manufacturing apparatus 400 illustrated in FIG. 10 is an apparatus that manufactures the image sensor 300 (FIG. 8) to which the present technique is applied.

The manufacturing apparatus 400 has a controlling unit 401 and a manufacturing unit 402. Moreover, the manufacturing apparatus 400 has an input unit 211, an output unit 212, a storage unit 213, a communication unit 214, and a drive 215 to which a removable media 221 is loaded.

The controlling unit 401 has basically the same configuration as the controlling unit 201, controls each portion of the manufacturing unit 402, and conducts controlling processes regarding manufacture of the image sensor 300.

The manufacturing unit 402 is controlled by the controlling unit 401, and conducts processes regarding manufacture of the image sensor 300 to which the present technique is applied to. As illustrated in FIG. 10, the manufacturing unit 402 has a CIS manufacturing unit 431, a LOGIC 1 manufacturing unit 432, a LOGIC 1 combining unit 433, a LOGIC 2 manufacturing unit 434, a LOGIC 2 combining unit 435, a filter forming unit 436, and a collecting lens forming unit 437.

### [Flow of Manufacturing Process]

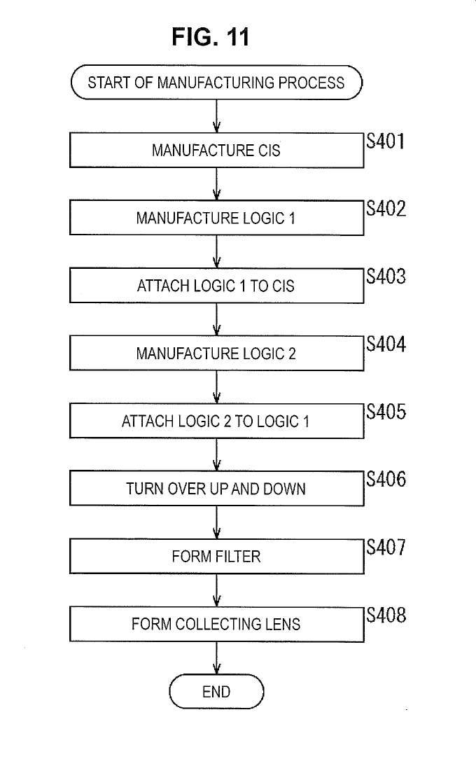

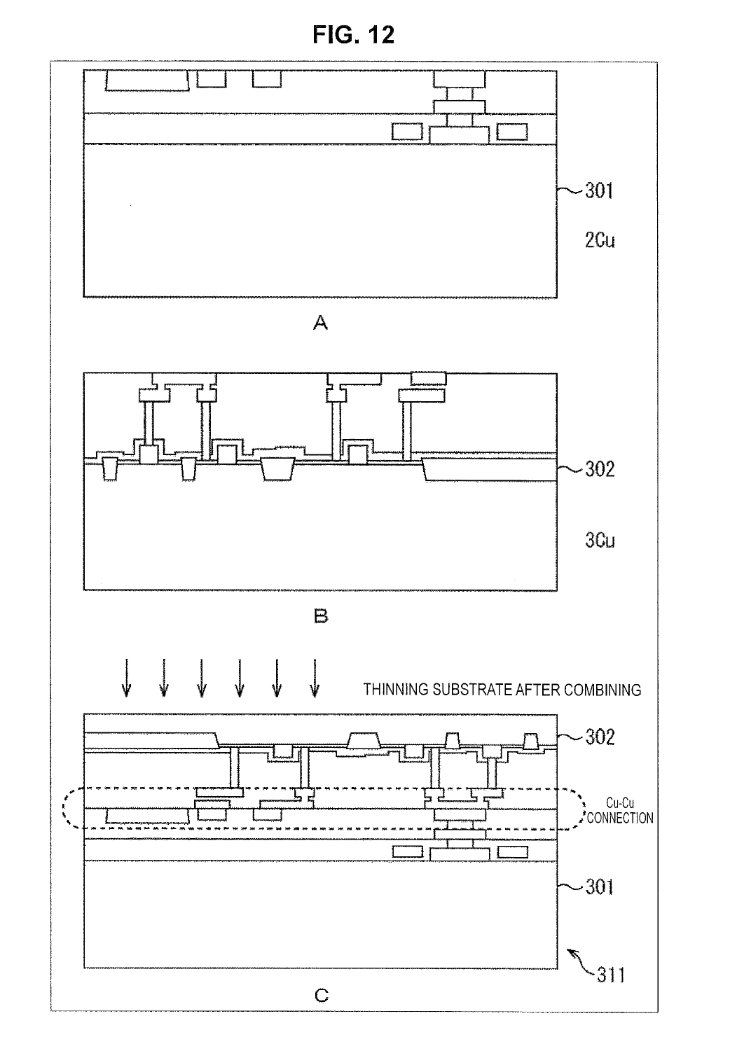

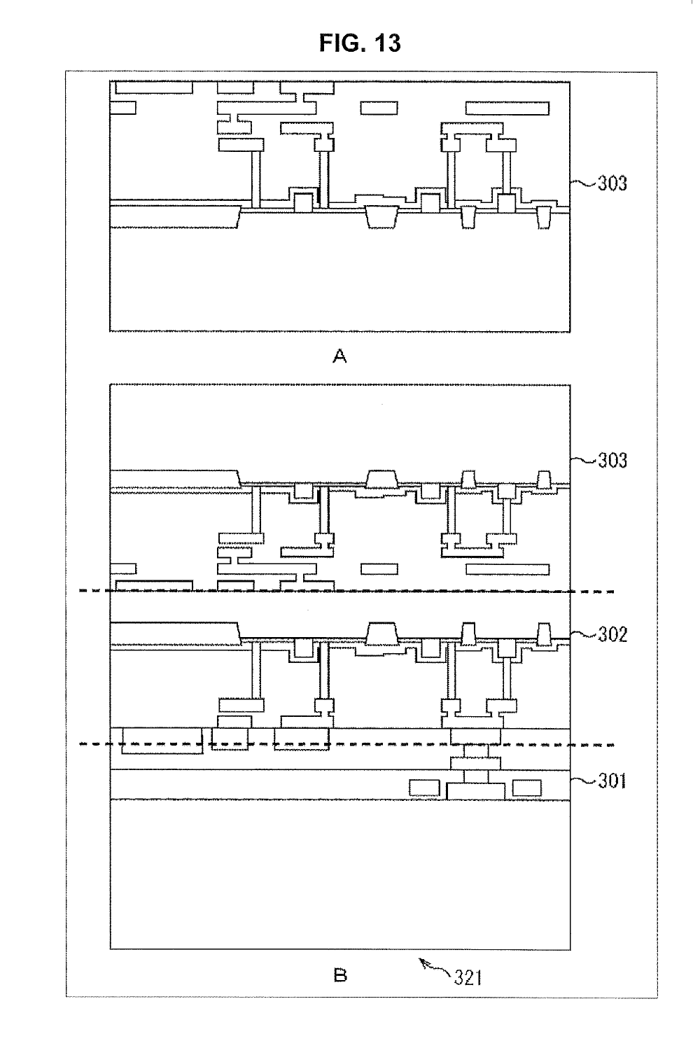

With reference to a flowchart of FIG. 11, an example of flow of manufacturing process performed by the manufacturing unit 402 is explained. The explanation is made with reference to FIG. 12 and FIG. 13, as may be necessary.

When the manufacturing process is started, the CIS manufacturing unit 431 is controlled by the controlling unit 401, and manufactures the image sensor chip (CIS) 301, using a silicon (Si) substrate supplied from the outside, at Step S401 (FIG. 12A). This process is conducted in essentially the same manner as, for example, the flow of manufacturing process of the image sensor 100 explained with reference to the flowchart of FIG. 3.

At Step S402, the LOGIC 1 manufacturing unit 432 is controlled by the controlling unit 401, and forms the logic circuit chip (Logic 1) 302 where the transistors such as the amplifier (Amp), the selector (Sel), the reset (Rst) for the pixel configuration of the image sensor chip (CIS) 301 are formed, using a silicon (Si) substrate supplied from the outside (FIG. 12B). This process is conducted in essentially the same manner as a manufacturing method of a logic circuit in the past.

At Step S403, the LOGIC 1 combining unit 433 is controlled by the controlling unit 401, turns over up and down the logic circuit chip (Logic 1) 302 that has been manufactured at Step S402, and overlays and combines the lower surface (the wiring side) of the logic circuit chip (Logic 1) 302, which has been turned over up and down, on the top surface (the wiring side) of the image sensor chip (CIS) 301 that has been manufactured at Step S401.

On this occasion, by attaching an inner-pixel wiring of the image sensor chip (CIS) 301 and the wiring of the logic circuit chip (Logic 1) 302, with respect to corresponding circuits for every pixel or for every plural pixels, the LOGIC 1 combining unit 433 connects the circuits of the both chips.

With this, an inner-pixel configuration of the CMOS image sensor is realized with a configuration where the logic circuits such as the amplifier (Amp), the selector (Sel), and the reset (Rst) are overlaid to the other side of a light incident surface of the photodiode. Therefore, a charge accumulation layer can be enlarged as explained using FIG. 9.

Incidentally, the LOGIC 1 combining unit 433 may use vias, thereby to connect the circuits of the both chips outside the pixel.

In the above manner, a device (CIS+Logic 1) 311 is manufactured in which the image sensor chip (CIS) 301 and the logic circuit chip (Logic 1) 302 are overlaid. Moreover, the LOGIC 1 combining unit 433 thins the substrate of the logic circuit chip (Logic 1) 302, which corresponds to the top surface of the device (CIS+Logic 1) 311 (FIG. 12C).

At Step S404, the LOGIC 2 manufacturing unit 434 is controlled by the controlling unit 401, and manufactures the logic chip (Logic 2) 303 where another logic circuit to be used for an input and output section for the pixel of the image sensor chip (CIS) 301 is formed, using a silicon (Si) substrate supplied from the outside (FIG. 13A). This process is conducted in essentially the same manner as a manufacturing method of a logic circuit in the past.

At Step S405, the LOGIC 2 combining unit 435 is controlled by the controlling unit 401, turns over up and down the logic circuit chip (Logic 2) 303 that has been manufactured at Step S404, and overlays and combines the lower surface (the wiring side) of the logic circuit chip (Logic 2) 303, which has been turned over up and down, on the top surface (the substrate side of the thinned logic circuit chip (Logic 1) 302) of the device (CIS+Logic 1) 311 that has been manufactured at Step S403. On this occasion, The LOGIC 1 combining unit 433 connects the respective circuits of the image sensor (CIS) 301, the logic circuit chip (Logic 1) 302, and the logic circuit chip (Logic 2) 303, by connecting the wiring of the logic circuit (Logic 2) 303 and the wiring of the device (CIS+Logic 1) 311, using vias.

In such a manner, a device (CIS+Logic 1+Logic 2) 321 is manufactured in which the image sensor chip (CIS) 301, the logic circuit chip (Logic 1) 302, and the logic circuit chip (Logic 2) 303 are piled with one another (FIG. 13B).

At Step S406, the LOGIC 2 combining unit 435 is controlled by the controlling unit 401, turns over the device (CIS+Logic 1+Logic 2) 321 up and down, and thins the substrate of the image sensor chip (CIS) 301, which corresponds to the top surface of the device (CIS+Logic 1+Logic 2) 321.

At Step S407, the filter forming unit 436 is controlled by the controlling unit 401, and forms a filter such as a color filter and an infrared filter on a pixel portion (the photodiode 111) of the image sensor chip (CIS) 301 on the top surface of the device (CIS+Logic 1+Logic 2) 321 whose substrate has been thinned at Step S406.

At Step S408, the collecting lens forming unit 437 is controlled by the controlling unit 401, and forms a collecting lens on the upper surface of the filter (on the photodiode 111) that has been formed at Step S406.

When the collecting lens is formed, the manufacturing unit 402 supplies the image sensor 300 manufactured as above to the outside, and completes the manufacturing process.

As above, the manufacturing apparatus 400 is capable of manufacturing the image sensor chip (CIS) 301, the logic circuit chip (Logic 1) 302, and the logic circuit chip (Logic 2) 303, through basically the same number of processes as that of a case where an image sensor in the past is manufactured, and only attaches one another, thereby to manufacture the image sensor 300 with ease.

Incidentally, an order of the processes described above may be arbitrarily changed, as long as no inconsistency arises.

### 3. Third Embodiment

### Image Sensor

It has been explained in FIG. 1 that the P− layer 123 and the N+ layer 124 in the form of a column are overlaid in the upper side of the photodiode 111 (the N region 121) in the drawing. However, without limiting to this, the P− layer 123 and the N+ layer 124 may be formed so as for a part or entirety thereof to be inside the N region 121 (to be embedded) regarding an up-and-down direction (a layered direction) in the drawing.

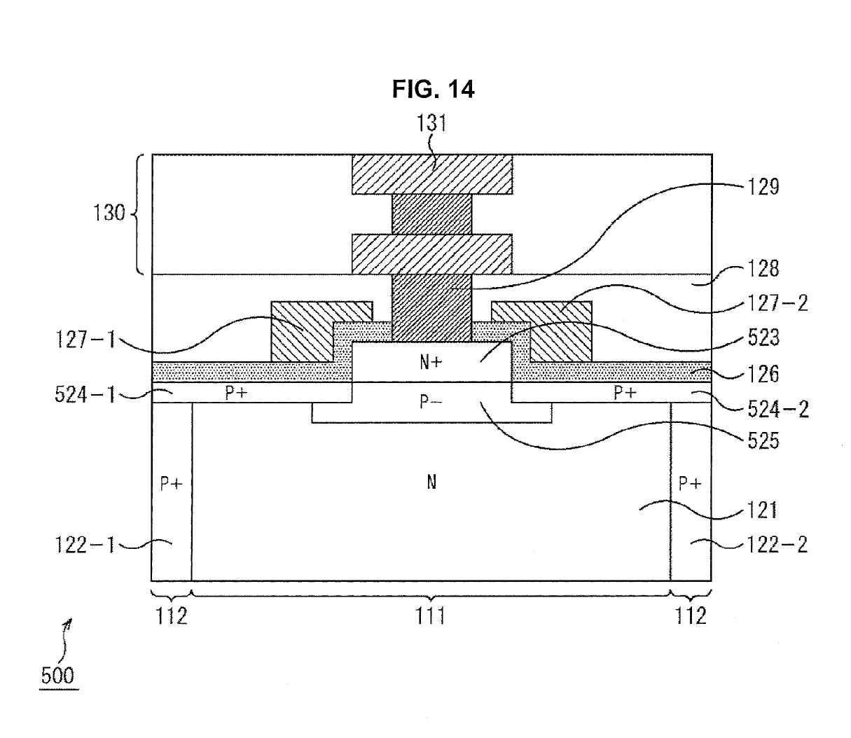

FIG. 14 is a cross-sectional view illustrating an example of a principal configuration regarding a part of an image sensor to which the present technique is applied. An image sensor 500 illustrated in FIG. 14 is basically the same image sensor as the image sensor 100 of FIG. 1, and has essentially the same configuration as the image sensor 100.

However, in the case of the image sensor 500, a P− layer 525, which is the channel portion of the TG 141, is formed inside the N region 121.

An N+ layer 523 of the FD 142 is formed so as to be piled in the upper side of the P− layer 525 in the drawing, as is the case with the N+ layer 124. Therefore, the N+ layer 523 is formed so as to be piled the photodiode 111.

A P+ layer 524 (a P+ layer 524-1 and a P+ layer 524-2) is formed in essentially the same manner as the P+ layer 125. Therefore, the P+ layer 524 and the P− layer 525 are formed on the top surface of the photodiode 111 in the drawing.

In this manner, a thickness of the image sensor 500 (a length in the up-and-down direction (the layered direction) in the drawing) can be smaller than that of the image sensor 100.

In addition, because the subsequent process operations can be promoted with a lower step difference, compared to a case of the image sensor 100, pattern forming of higher accuracy can be conducted for the image sensor 500. Moreover, because step portions of flanks of the FD portion can be formed of a further robust P+ type, resistance properties against noises such as white dots can be improved.

### [Manufacturing Apparatus]

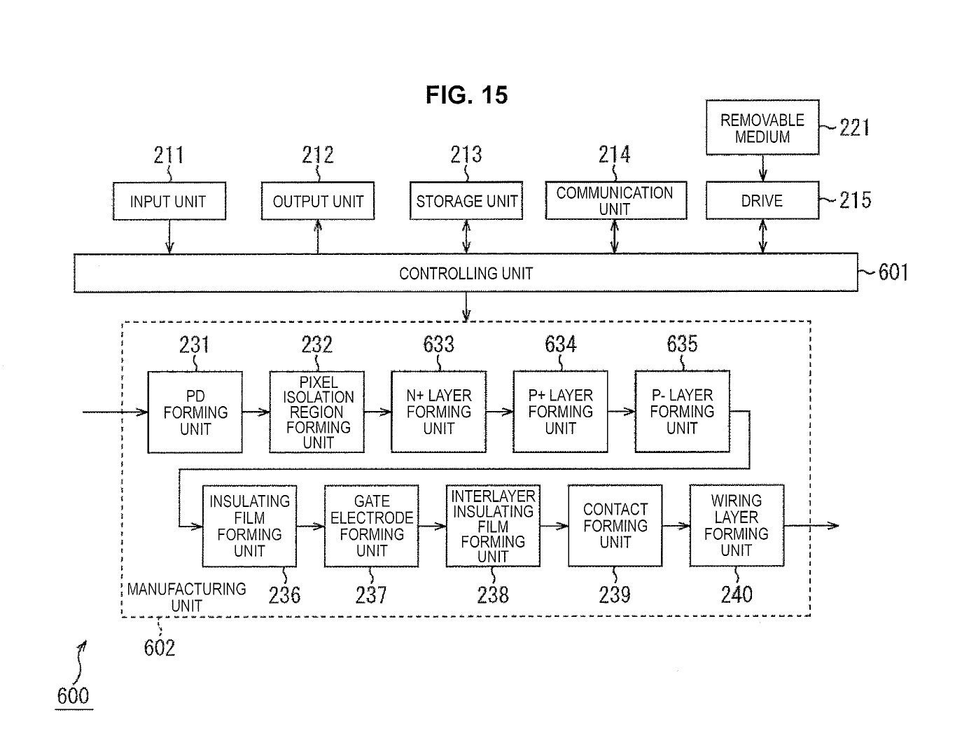

FIG. 15 is a block diagram illustrating an example of a principal configuration of a manufacturing apparatus for manufacturing an image sensor to which the present technique is applied. A manufacturing apparatus 600 illustrated in FIG. 15 is an apparatus that manufactures the image sensor 500 (FIG. 14) to which the present technique is applied.

The manufacturing apparatus 600 has a controlling unit 601 and a manufacturing unit 602. Moreover, the manufacturing apparatus 600 has an input unit 211, an output unit 212, a storage unit 213, a communication unit 214, and a drive 215 to which a removable media 221 is loaded.

The controlling unit 601 has basically the same configuration as the controlling unit 201, controls each portion of the manufacturing unit 602, and conducts controlling processes regarding manufacture of the image sensor 500.

The manufacturing unit 602 is controlled by the controlling unit 601, and conducts processes regarding manufacture of the image sensor 600 to which the present technique is applied. As illustrated in FIG. 15, the manufacturing unit 602 has basically the same configuration as the manufacturing unit 202 (FIG. 2). However, in the place of the P− layer forming unit 233, the N+ layer forming unit 234, and the P+ layer forming unit 235, the manufacturing unit 602 has an N+ layer forming unit 633, a P+ layer forming unit 634, and a P− layer forming unit 635.

### [Flow of Manufacturing Process]

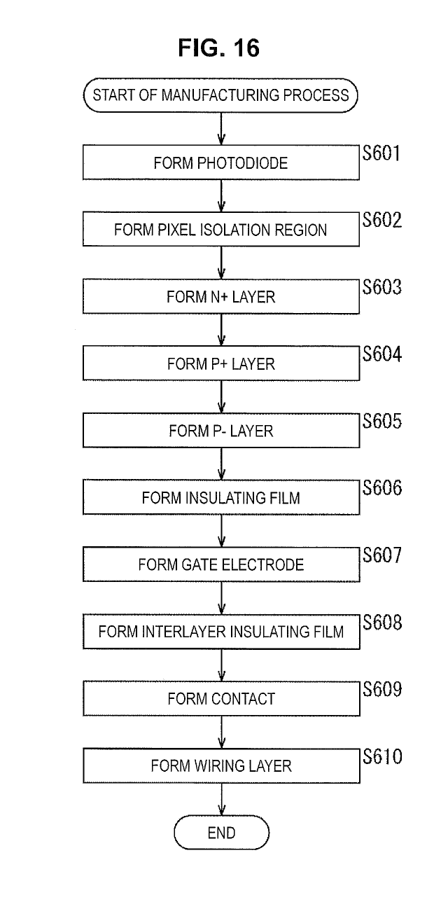

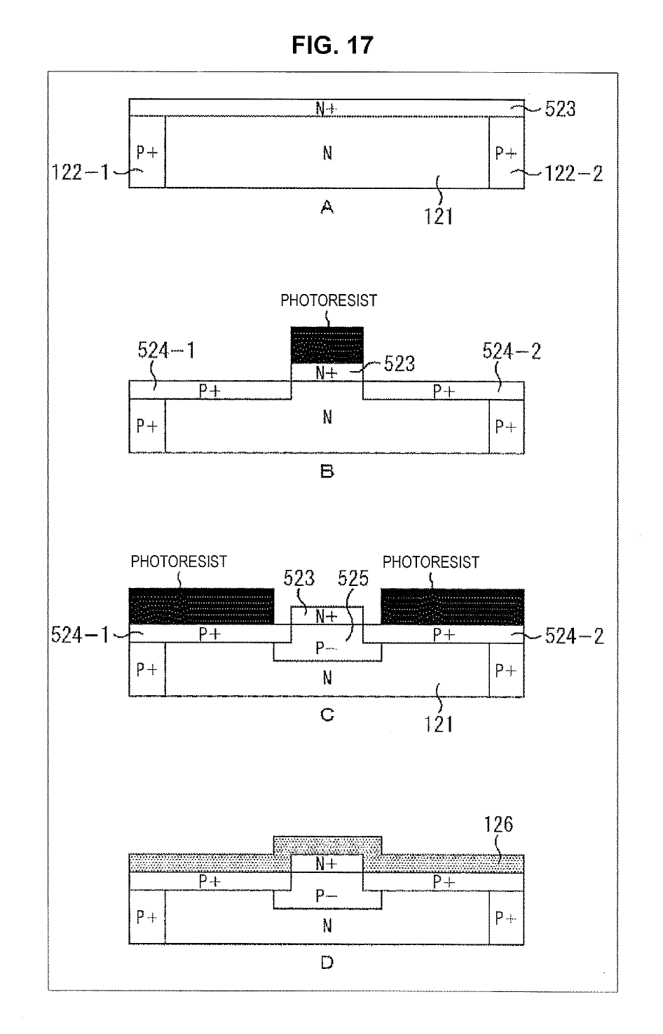

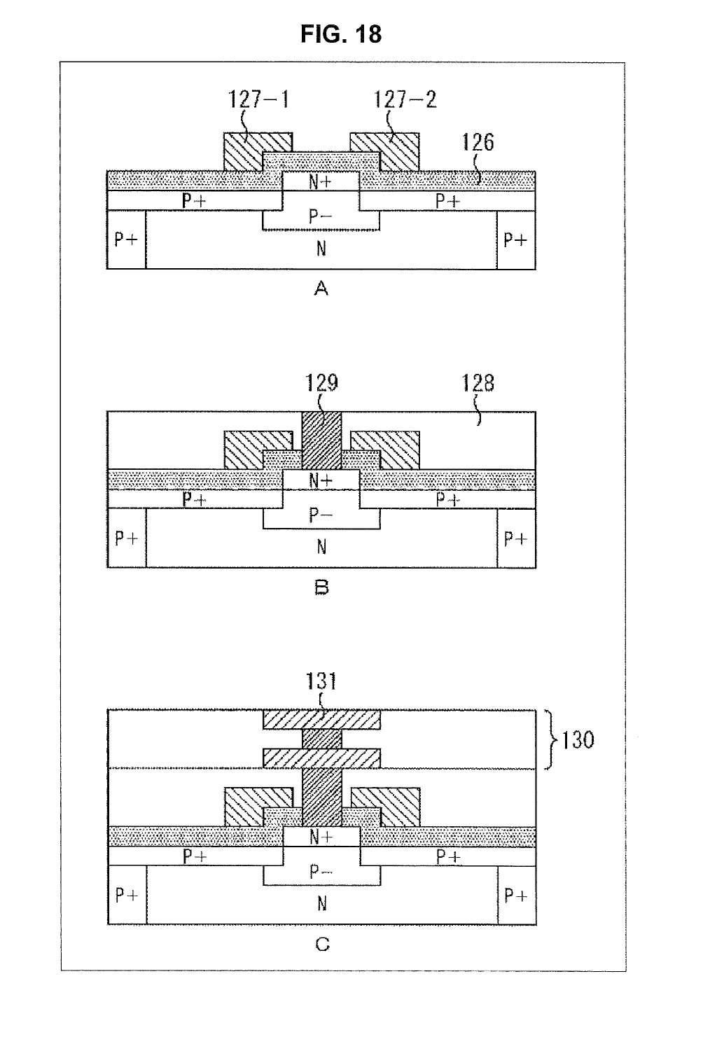

With reference to a flowchart of FIG. 16, an example of flow of manufacturing process performed by the manufacturing unit 602 is explained. The explanation is made with reference to FIG. 17 and FIG. 18, as may be necessary.

Processes at Step S601 and Step S602 are performed in essentially the same manner as the processes at Step S101 and Step S102 of FIG. 3, respectively.

At Step S603, the N+ layer forming unit 633 is controlled by the controlling unit 601, and forms the N+ layer 523 of the FD 142 on the upper surfaces of the pixel isolation region 112 (the P+ region 12) and the photodiode 111 (the N region 121) of a device that has been supplied from the pixel isolation region forming unit 232 (FIG. 17A).

At Step S604, the P+ layer forming unit 634 is controlled by the controlling unit 601, removes a part of the N+ layer 523 of a device that has been supplied from the N+ layer forming unit 633, and forms the P+ layer 524 on the upper surfaces of the N region 121 and the P+ region 122. More specifically, the P+ layer forming unit 634 applies a photoresist on the upper surface of the N+ layer 523, and forms a photoresist opening region, except a part that turns out to be the FD 142, employing a mask and a photolithography technique. Then, the P+ layer forming unit 634 removes the N+ layer 523 in the photoresist opening region by a method such as dry etching. Namely, the P+ layer forming unit 634 leaves the part that turns out to be the FD 142 in the N+ layer 523, and removes the other parts of the N+ layer 523. With this, the N+ layer 523 layered in the form of a column is formed. After this, the P+ layer forming unit 634 forms the P+ layer 524 in the photoresist opening region (a part except the N+ layer 523 layered in the form of a column) (FIG. 17B), and removes the photoresist left on the upper surface of the N+ layer 523 by ashing.

At Step S605, the P− layer forming unit 635 is controlled by the controlling unit 601, and forms the P− layer 525. More specifically, the P− layer forming unit 635 applies a photoresist, sets a region that includes the FD 142 and is a little wider than the FD 142 as a photoresist opening region, employing a mask and a photolithography technique in essentially the same manner as Step S604, and then forms the P− layer 525 in the N region 121 in the photoresist opening region (FIG. 17C). Because a concentration of this P− layer 525 is sufficiently lower than an N type impurity concentration formed in the N+ layer 523 of the FD 142, the N+ layer 523 is not influenced. Then, the P− layer forming unit 635 removes the photoresist left on the upper surface of the P+ layer 524 by ashing.

Processes at Step S606 through Step S610 are performed in essentially the same manner as the processes at Step S106 through Step S110 (FIG. 17D, and FIG. 18A through FIG. 18C), respectively.

When the wiring layer 130 is formed, the manufacturing unit 602 supplies the image sensor 500 manufactured as above to outside, and completes the manufacturing process.

As above, the manufacturing apparatus 600 is capable of manufacturing the image sensor 500 with ease, through basically the same number of processes as that of a case where an image sensor in the past is manufactured.

Incidentally, an order of the processes described above may be arbitrarily changed, as long as no inconsistency arises.

### [Additional Statement]

Incidentally, in the example of FIG. 14, (a part or entirety of) the gate electrode 127 may also be formed (embedded) inside the N region 121.

Moreover, a part or entirety of the N+ layer 523 may also be formed (embedded) inside the N region 121, thereby to further reduce a thickness of the image sensor. Namely, a degree (height) to which the TG 141 and the FD 142 configured so as to be layered at least partly are exposed outward along the layered direction from the upper surface opposite to the light incident surface of the photodiode 111, namely in other words, a degree (depth) to which the TG 141 and the FD 142 are formed inside the photodiode 111 is arbitrary.

As a ratio of the TG 141 and the FD 142 formed inside the photodiode 111 becomes larger, the image sensor is formed thinner. However, because the N region 121 becomes small accordingly, an amount of accumulated charge becomes small.

### 4. Fourth Embodiment

### Image Sensor

In the foregoing, explanations are made about the photodiode, the TG, and the FD. The P− layers of channel portions of the transistors such as the amplifier (Amp), the selector (Sel), the reset (Rst) may be formed so as to be piled on the P+ layer.

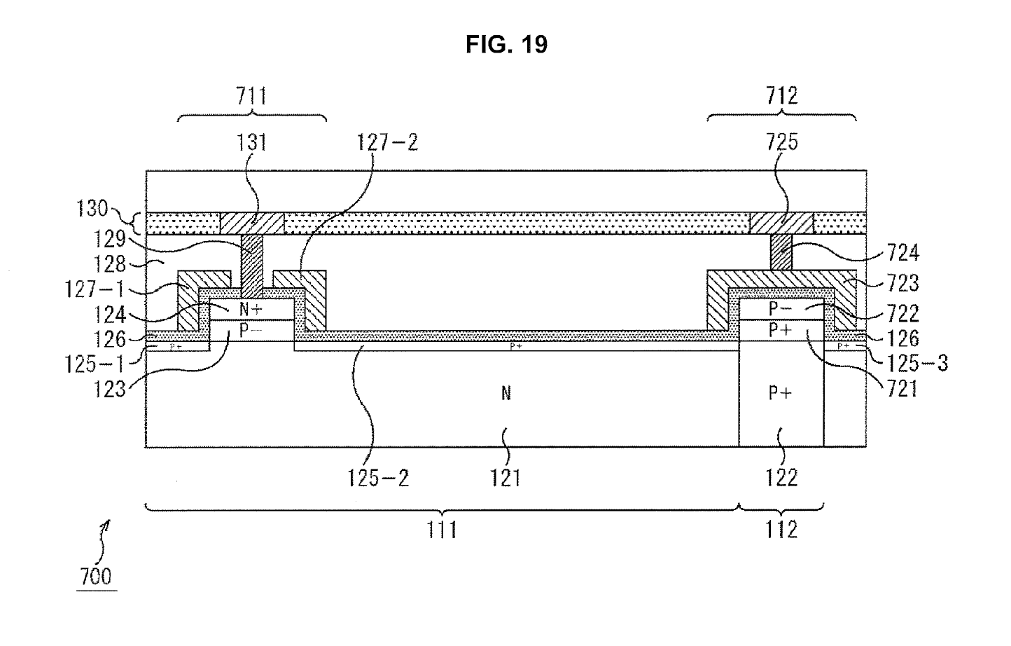

FIG. 19 is a cross-sectional view illustrating an example of a principal configuration of an image sensor in that case. An image sensor 700 illustrated in FIG. 19 has a TR portion 712 that includes transistors such as the amplifier (Amp), the selector (Sel), the reset (Rst), in addition to an FD/TG portion 711 which is an image sensor that is basically the same as the image sensor 100 of FIG. 1.

The TR portion 712 is formed in the upper side of the pixel isolation region 112 (the P+ region 122). FIG. 19 illustrates a cross-sectional view of a channel portion of the TR portion 712. As illustrated in FIG. 19, in the TR portion 712, a P− layer 722 as a channel portion is formed so as to be piled in the upper side of a P+ layer 721 in the drawing. Namely, the channel portion of the TR portion 712 is formed in the form of a column. Incidentally, N layers of a source portion and a drain portion of the TR portion 712 are apposed with respect to the channel portion (not illustrated). The insulating film 126 is formed on the upper surface of the channel portion, and a gate electrode 723 is formed so as to cover the channel portion further from the above.

Moreover, the interlayer insulating film 128 is formed in the upper sides of the gate electrode 723 and the insulating film 126 in the drawing. A contact 724 is formed in the upper side of the gate electrode 723 so as to go through the interlayer insulating film 128.

In addition, in the upper side of the interlayer insulating film 128 in the drawing, the wiring layer 130 including a wiring 725 that connects the FD/TG portion 711 and the TR portion 712. Further in the upper side of the wiring layer 130 in the drawing, an interlayer insulating film may be naturally formed.

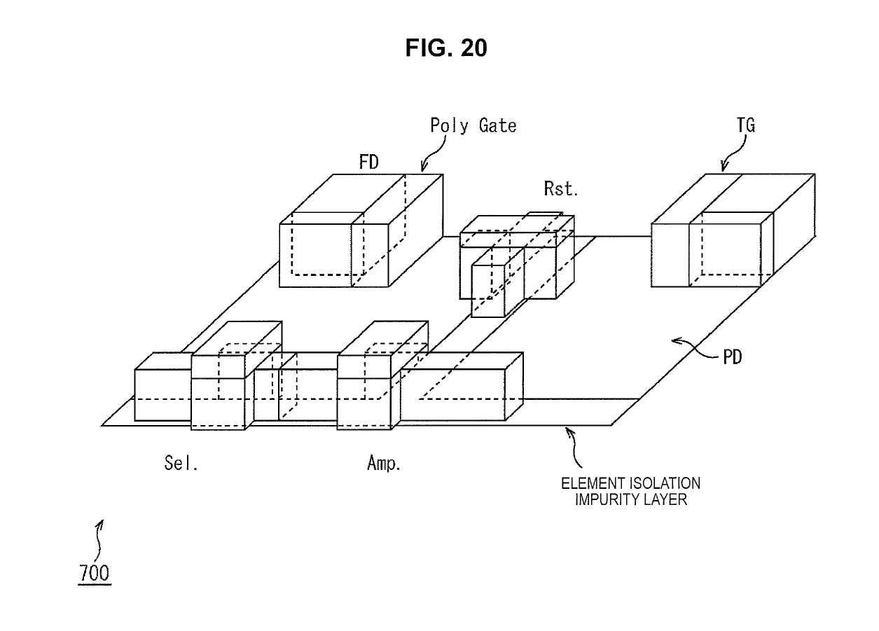

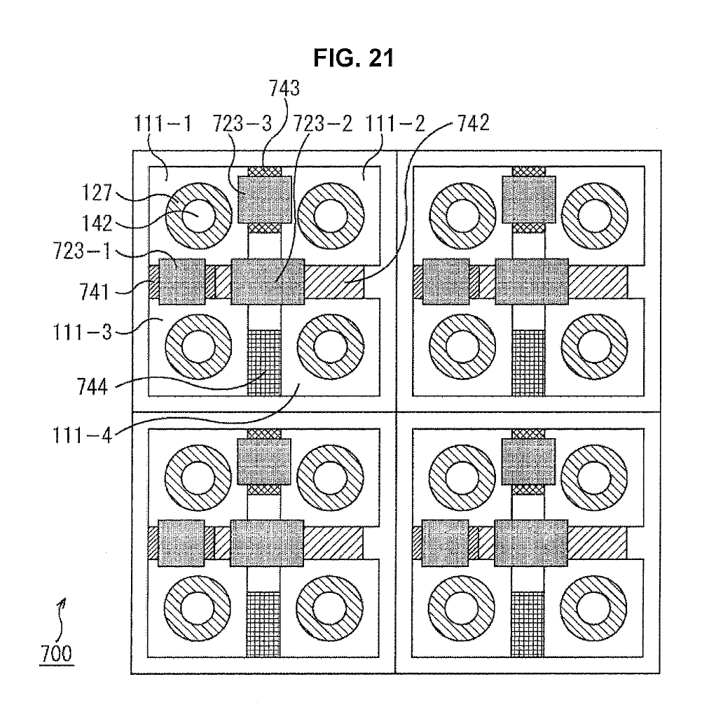

FIG. 20 is a perspective view of configurations of the FD/TG portion 711 and the TR portion 712 of the image sensor 700, which are seen obliquely from the above. FIG. 21 is a plan view seen from the upper side of FIG. 19.

By taking such configurations, a gate width and a gate length of the channel portions of the TR portion 712 can be lengthened. With this, ON/OFF characteristics, 1/f noise characteristics, or the like can be improved.

In addition, as with the selector 741, the amplifier 742, and the reset 743 illustrated in FIG. 21, the TR portion 712 is formed in the pixel isolation region 112. Therefore, the photodiode 111 can be enlarged.

### [Manufacturing Apparatus]

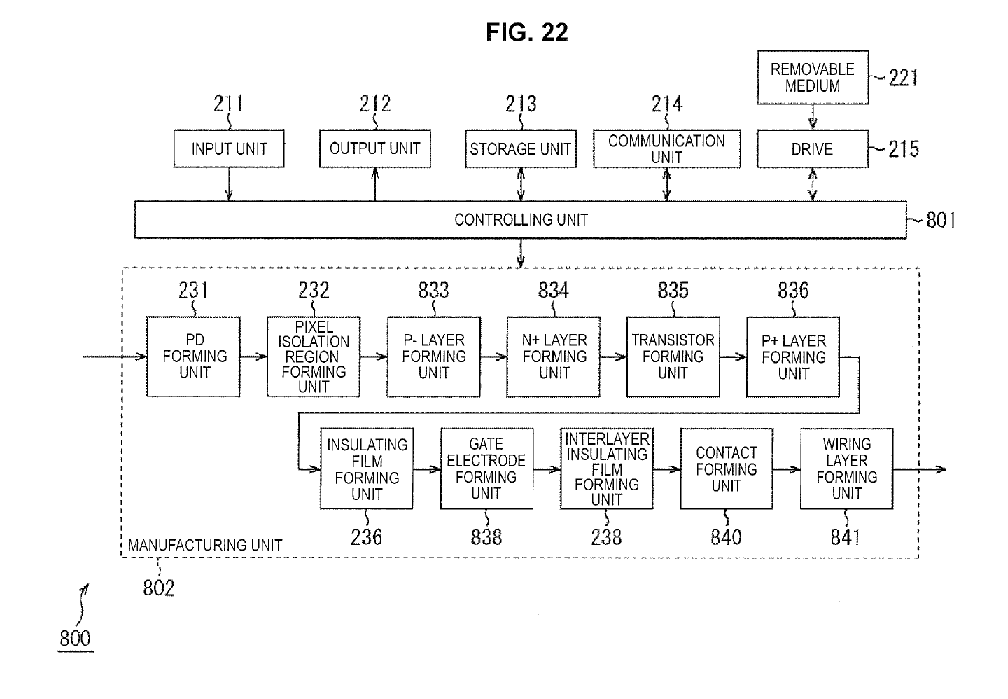

FIG. 22 is a block diagram illustrating an example of a principal configuration of a manufacturing apparatus for manufacturing an image sensor to which the present technique is applied. A manufacturing apparatus 800 illustrated in FIG. 22 is an apparatus that manufactures the image sensor 700 (FIG. 19) to which the present technique is applied.

The manufacturing apparatus 800 has a controlling unit 801 and a manufacturing unit 802. Moreover, the manufacturing apparatus 800 has an input unit 211, an output unit 212, a storage unit 213, a communication unit 214, and a drive 215 to which a removable media 221 is loaded.

The controlling unit 801 has basically the same configuration as the controlling unit 201, controls each portion of the manufacturing unit 802, and conducts controlling processes regarding manufacture of the image sensor 700.

The manufacturing unit 802 is controlled by the controlling unit 801, and conducts processes regarding manufacture of the image sensor 700 to which the present technique is applied. As illustrated in FIG. 22, the manufacturing unit 802 has basically the same configuration as the manufacturing unit 201 (FIG. 2). However, in the place of the P− layer forming unit 233, the N+ layer forming unit 234, the P+ layer forming unit 235, the gate electrode forming unit 237, the contact forming unit 239, and the wiring layer forming unit 240, the manufacturing unit 802 has a P− layer forming unit 833, an N+ layer forming unit 834, a transistor forming unit 835, a P+ layer forming unit 836, a gate electrode forming unit 838, a contact forming unit 840, and a wiring layer forming unit 841.

### [Flow of Manufacturing Process]

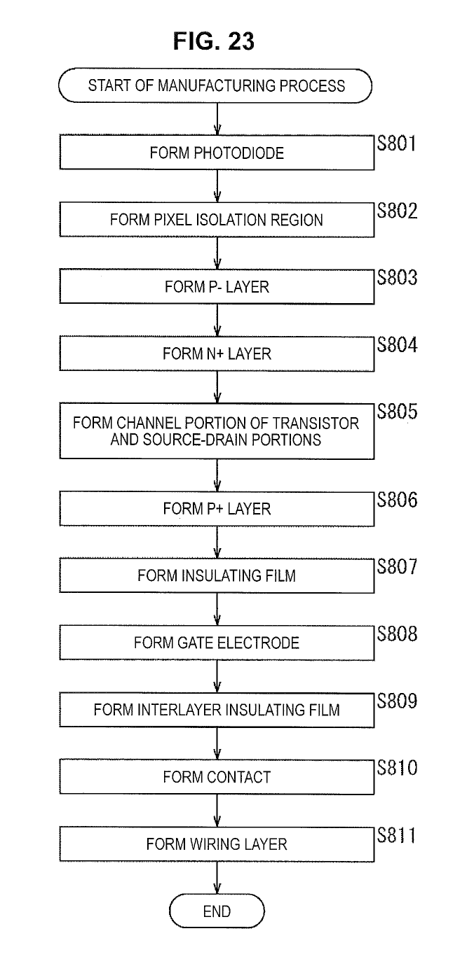

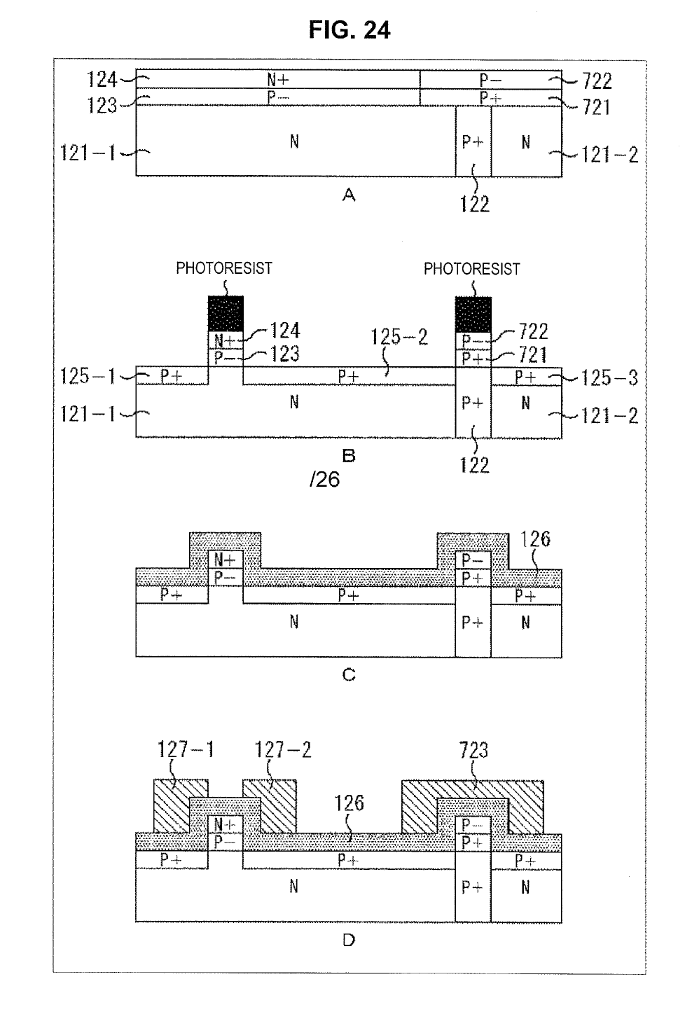

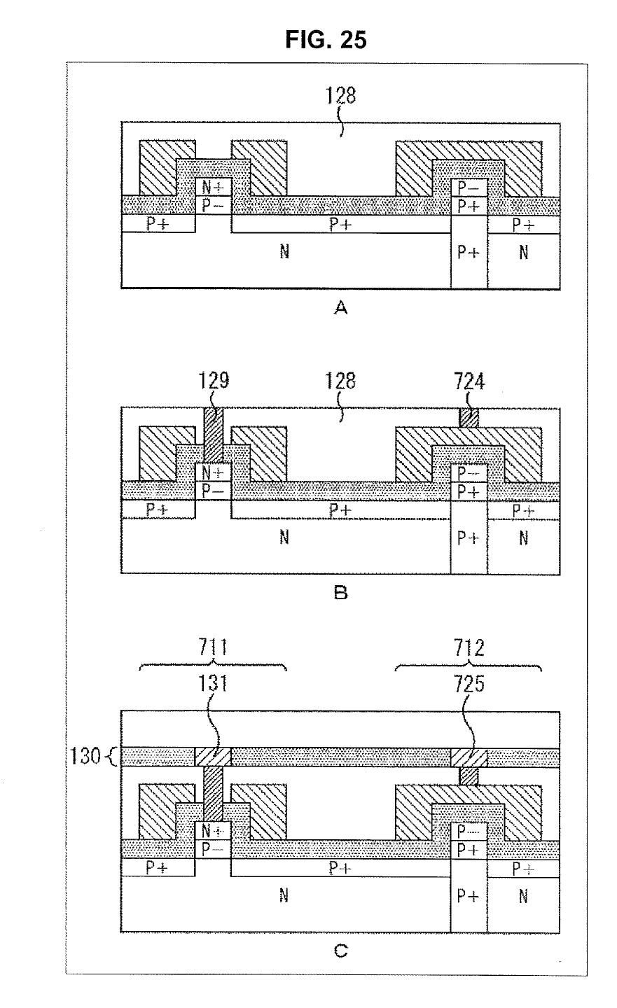

With reference to a flowchart of FIG. 23, an example of flow of manufacturing process performed by the manufacturing unit 802 is explained. The explanation is made with reference to FIG. 24 and FIG. 25, as may be necessary.

Processes at Step S801 and Step S802 are performed in essentially the manner as the processes at Step S101 and Step S102 of FIG. 3, respectively.

At Step S803, the P− layer forming unit 833 is controlled by the controlling unit 801, and forms the P− layer 123 of the TG 141 on the upper surface of the photodiode 111 (the N region 121) of a device that has been supplied from the pixel isolation region forming unit 232.

At Step S804, the N+ layer forming unit 834 is controlled by the controlling unit 801, and forms the N+ layer 124 of the FD 142 on the upper surface of the P− layer 123 on the N region 121 of the photodiode 111 of a device that has been supplied from the P− layer forming unit 833.

At Step S805, the transistor forming unit 835 is controlled by the controlling unit 801, so that the channel portion (the P− layer 722) to be overlaid to the P+ layer 721 and source-drain portions (not illustrated) are formed in the upper side of the pixel isolation region 112 (the P+ region 122) of a device that has been supplied from the N+ layer forming unit 834 in the drawing (FIG. 24A).

Incidentally, as with the example illustrated in FIG. 24A, the P+ layer 721 and the P− layer 722 may be formed as films in the upper sides of the pixel isolation region 112 and parts of the photodiode 111 in the drawing.

At Step S806, the P+ layer forming unit 836 is controlled by the controlling unit 601, removes a part of each of the P− layer 123 and the N+ layer 124, and the P+ layer 721 and the P− layer 722 of a device that has been supplied from the transistor forming unit 835, and forms the P+ layer 125 on the upper surface of the N region 121.

More specifically, the P+ layer forming unit 836 applies a photoresist on the upper surfaces of the N+ layer 124 and the P− layer 722, and forms a photoresist opening region in areas except a part that turns out to be the FD/TG portion 711 and except a part that turns out to be the TR portion 712, employing a mask and a photolithography technique. Then, the P+ layer forming unit 836 removes the P− layer 123 and the N+ layer 124, and the P+ layer 721 and the P− layer 722 in the photoresist opening region by a method such as dry etching. Namely, the P+ layer forming unit 834 leaves parts of the P− layer 123 and the N+ layer 124 that turn out to be the FD/TG portion 711, and parts of the P+ layer 721 and the P− layer 722 that turn out to be the TR portion 712; and removes the other parts of each layer of the P− layer 123, the N+ layer 124, the P+ layer 721, and the P− layer 722. With this, not only the P− layer 123 and the N+ layer 124 layered in the form of a column but also the P+ layer 721 and the P− layer 722 formed in the form of a column are formed.

After that, the P+ layer forming unit 836 forms the P+ layer 125 in the photoresist opening region (FIG. 24B), and removes the photoresist left on the upper surfaces of the P− layer 722 and the N+ layer 124 by ashing.

A process at Step S807 is performed in essentially the same manner as Step S106 (FIG. 24C).

At Step S808, the gate electrode forming unit 838 is controlled by the controlling unit 801, and forms the gate electrode 127 so that the gate electrode 127 surrounds (covers) the perimeter of the P− layer 123 and the N+ layer 124 formed in the form of a column from the above of the insulating film 126 of a device that has been supplied from the insulating film forming unit 236. In addition, the gate electrode forming unit 838 forms the gate electrode 723 so that the gate electrode 723 covers the P+ layer 721 and the P− layer 722 formed in the form of a column from the above of the insulating film 126 of device (FIG. 24D).

More specifically, the gate electrode forming unit 838 forms a film of a gate electrode material such as poly silicon from the above of the insulating film 126, and conducts applying a photoresist, forming a photoresist opening by a mask and a photolithography technique, and dry etching, thereby to process the film and to form the gate electrode 127 and the gate electrode 723.

A process at Step S809 is performed in essentially the same manner as Step S108 (FIG. 25A).

At Step S810, the contact forming unit 840 is controlled by the controlling unit 801, and forms the contact 129 so that the contact 129 goes through the interlayer insulating film 128 and the insulating film 126 until the N+ layer 124 from the upper surface of a device that has been supplied from the interlayer insulating film forming unit 238. Moreover, the contact forming unit 840 forms a contact 724 so that the contact 724 goes through the interlayer insulating film 128 until the gate electrode 723 from the upper surface of the device (FIG. 25B).

At Step S811, the wiring layer forming unit 841 is controlled by the controlling unit 801, and forms, for example, the wiring layer 130 including the wiring 131 connected to the contact 129 of the FD/TG portion 711 and the wiring 725 connected to the contact 724 of the TR portion 712 on the upper surface of a device that has been supplied from the contact forming unit 840 (FIG. 25C). In the upper side of the wiring layer 130 in the drawing, an interlayer insulating film may be further formed.

When the wiring layer is formed, the manufacturing unit 802 supplies the image sensor 700 manufactured as above to the outside, and completes the manufacturing process.

As above, the manufacturing apparatus 800 is capable of manufacturing the image sensor 700 with ease, through basically the same number of processes as that of a case where an image sensor in the past is manufactured.

Incidentally, an order of the processes described above may be arbitrarily changed, as long as no inconsistency arises.

In addition, although only one TR portion 712 is illustrated in FIG. 19, the TR portion 712 is formed as at least one of the amplifier (Amp), the selector (Sel), and the reset (Rst) in reality.

### 5. Fifth Embodiment

### Imaging Apparatus

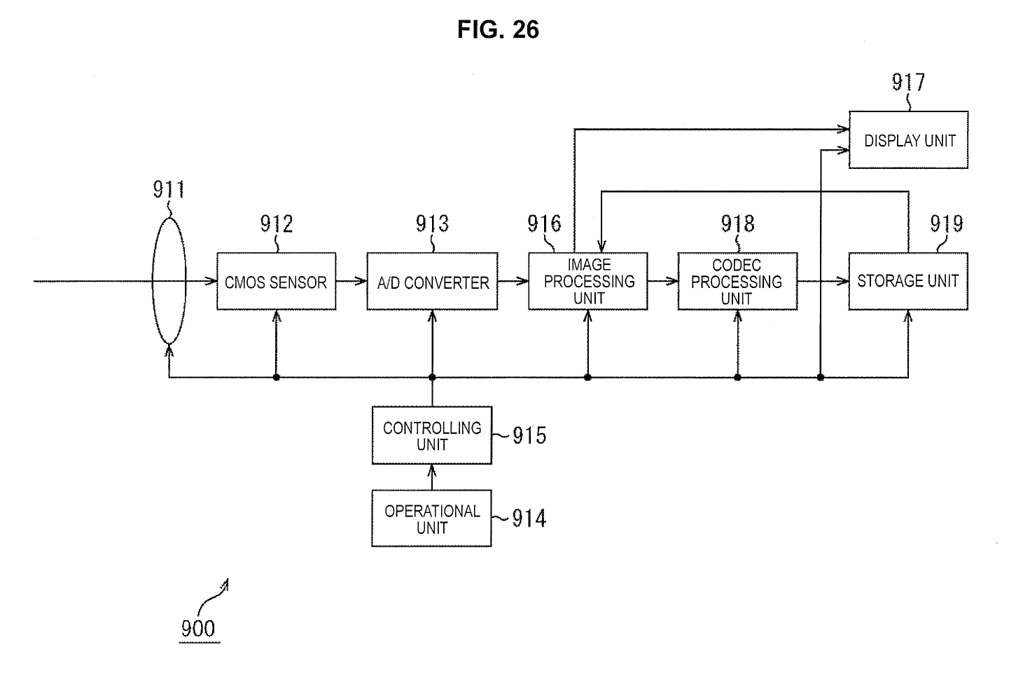

FIG. 26 is a view illustrating an example of a configuration of an imaging apparatus to which the present technique is applied. An imaging apparatus 900 illustrated in FIG. 26 is an apparatus that captures an image of an object and outputs the image of the object, as an electrical signal.

As illustrated in FIG. 26, the imaging apparatus 900 has a lens unit 911, a CMOS sensor 912, an A/D conversion unit 913, an operational unit 914, a controlling unit 915, an image processing unit 916, a display unit 917, a codec processing unit 918, and a recording unit 919.

The lens unit 911 adjusts focus of the object, collects light from a focused position, and supplies to the collected light to the CMOS sensor 912.

The CMOS sensor 912 performs photoelectric conversion on the light from the object, which has been supplied through the lens unit 911, and supplies the electric signal to the A/D converter 913.

The A/D converter 913 converts the electric signal for every pixel, which has been supplied at a predetermined timing, to a digital image signal (also referred to as a pixel signal or an image data, arbitrarily), and supplies the digital image signal to the image processing unit 916 sequentially at a predetermined timing.

The operational unit 914 is composed of, for example, a jog-dial (trademark), a key, a button, a touch panel, or the like, receives an operational input by a user, and supplies to the controlling unit 915 a signal that corresponds to the operational input.

The controlling unit 915 controls performances of the lens unit 911, the CMOS sensor 912, the A/D converter 913, the image processing unit 916, the display unit 917, the codec processing unit 918, and the recording unit 919 in accordance with signals corresponding to user's operational inputs input from the operational unit 914, thereby to cause each unit to conduct processes regarding imaging.

The image processing unit 916 practices, for example, various imaging processes such as black level correction, color mixture correction, defect correction, demosaic processing, matrix processing, gamma correction, and YC conversion, which have been described, with respect to the image signal that has been supplied from the A/D converter 913. The image processing unit 916 supplies an image signal that goes through the imaging processes to the display unit 917 and the codec processing unit 918.

The display unit 917 is composed as, for example, a liquid crystal display or the like, and displays the image of the object in accordance with the image signal from the image processing unit 916.

The codec processing unit 918 practices an encoding process of a predetermined scheme with respect to the image signal from the image processing unit 916, and supplies image data obtained as a result of the encoding process to the recording unit 919.

The recording unit 919 records the image data from the codec processing unit 918. The image data recorded in the recording unit 919 is read out to the image processing unit 916, as may be necessary, and thus supplied to the display unit 917 on which a corresponding image is displayed.

As the CMOS sensor 12 of such an imaging apparatus 900, by applying the image sensor where the FD and the channel portion (P− layer) of the TG are layered so as to be piled with each other at least partly (for example, the image sensor 100 of FIG. 1, the image sensor 300 of FIG. 8, the image sensor 500 of FIG. 15, or the image sensor 700 of FIG. 19) as described above, the charge accumulation region can be enlarged in the imaging apparatus 900. With this, an amount of accumulated charge can be increased, and image quality degradation can be suppressed.

Incidentally, the image sensor to which the present technique is applied may be applied to arbitrary information processing apparatuses having an imaging function, such as a digital still camera, a video camera, a cellular phone, a smart phone, a tablet-type device, and a personal computer, without limiting to the imaging apparatus of the above-described configuration. In addition, the image sensor to which the present technique is applied may also be applied to a camera module that is loaded in other information processing apparatuses and used (or loaded as an incorporated device).

The series of processes described above may be performed either by hardware or by software. When the above-described series of processes are performed by software, the programs constituting the software are installed through a network or a recording medium.

This recording medium is composed of the removable medium 221 that has a program recorded therein and is distributed for delivering a program to a user, separately from an apparatus body, as illustrated, for example, in FIG. 2, FIG. 10, FIG. 15, and FIG. 22. The removable medium 221 includes a magnetic disk (including a flexible disk) and an optical disk (including a CD-ROM and a DVD), and further a magnetooptical disk (including a Mini Disc (MD)), a semiconductor memory, and the like. In addition, the recording medium described above may be composed of not just such a removable disk 221, but a ROM, a hard disk included in the storage unit 213, or the like having a program recorded therein, each of which is incorporated in advance in the apparatus body and delivered to a user.

Incidentally, a program executed by a computer may be a program according to which processes are performed in chronological order along an order explained in this specification, or a program according to which processes are performed in parallel, or at a necessary timing such as at the time when readout is performed.

In addition, in this specification, steps of describing the program recorded in the recording medium include not just processes conducted in chronological order in accordance with an order written therein, but processes conducted not necessary in chronological order but in parallel or independently.

In addition, in this specification, a system refers to entirety of an apparatus composed of plural devices (apparatuses).

Moreover, in the foregoing, a configuration explained as one apparatus (or processing unit) may be divided and composed of plural apparatuses (or processing units). Conversely, configurations explained as plural apparatuses (or processing units) in the above may be consolidated and composed as one apparatus (or processing unit). In addition, configurations except those explained above may be naturally added to a configuration of each apparatus. Furthermore, a part of a configuration of a certain device (or processing unit) may be included in a configuration of another apparatus (or another processing unit), as long as the configuration and the operation as the entirety of the system are substantially the same. Namely, the present technique is not limited to the embodiments described above, but various modifications may be made thereto without departing from the scope of the technique.

Additionally, the present technology may also be configured as below.

(1)

An image sensor including:

a channel portion of a readout transistor that constitutes a pixel; and

a floating diffusion,

wherein the channel portion and the floating diffusion are formed so as to be overlaid with each other at least partly.

(2)

The image sensor according to (1), wherein the channel portion and the floating diffusion are partly or entirely exposed outside a photodiode that constitutes the pixel.

(3)

The image sensor according to (1) or (2), wherein the channel portion and the floating diffusion are formed in a form of a column on a surface of a photodiode that constitutes the pixel.

(4)

The image sensor according to any one of (1) to (3), wherein the channel portion and the floating diffusion are formed within a region of a photodiode that constitutes a single pixel.

(5)

The image sensor according to any one of (1) to (4), wherein the channel portion and the floating diffusion are shared by a plurality of pixels.

(6)

The image sensor according to any one of (1) to (5), wherein a gate electrode of the readout transistor is formed so as to partly or entirely surround side surfaces of the channel portion and the floating diffusion.

(7)

The image sensor according to any one of (1) to (6), further including:

a first chip in which the readout transistor, the floating diffusion, and a photodiode that constitutes the pixel are formed; and

a second chip in which a transistor for amplification, a transistor for selection, and a transistor for reset that constitute the pixel are formed,

wherein the first chip and the second chip are overlaid and combined with each other.

(8)

The image sensor according to (7), wherein the first chip and the second chip are combined so that a wiring within the pixel of the first chip and a wiring of the second chip are attached, with respect to corresponding circuits for every pixel or for every plurality of pixels.

(9)

The image sensor according to (7), wherein a third chip in which a logic circuit including a transistor of an output section or an input section of the pixel is further overlaid and combined with the second chip combined with the first chip.

(10)

The image sensor according to any one of (1) to (9), wherein a P− layer of a channel portion of at least one of a transistor for amplification, a transistor for selection, and a transistor for reset that constitute the pixel is formed so as to be piled on a P+ layer.

(11)

A manufacturing apparatus that manufactures an image sensor, the manufacturing apparatus including:

a channel forming unit that forms a channel portion of a readout transistor that constitutes a pixel of the image sensor; and

a floating diffusion forming unit that forms a floating diffusion so that the floating diffusion and the channel portion formed by the channel forming unit is overlaid with each other at least partly.

(12)

The manufacturing apparatus according to (11), further including

a photodiode forming unit that forms a photodiode,

wherein the channel forming unit forms the channel portion on a surface of the photodiode formed by the photodiode forming unit, and

wherein the floating diffusion forming unit forms the floating diffusion so that the floating diffusion is overlaid to the channel portion formed on the surface of the photodiode.

(13)

The manufacturing apparatus according to (12),

wherein the floating diffusion forming unit forms the floating diffusion over the surface of the photodiode formed by the photodiode forming unit, and

wherein the channel forming unit forms the channel portion inside the photodiode so that the channel portion is overlaid to the floating diffusion formed by the floating diffusion forming unit.

(14)

The manufacturing apparatus according to any one of (11) to (13), further including

a transistor forming unit that forms at least one of a transistor for amplification, a transistor for selection, and a transistor for reset that constitute the pixel is formed so that a P− layer of each channel portion is piled on a P+ layer.

(15)

The manufacturing apparatus according to any one of (11) to (14), further including:

a manufacturing unit that manufactures a second chip in which a transistor for amplification, a transistor for selection, and a transistor for reset that constitute the pixel are formed, as a chip different from a first chip in which the readout transistor and the floating diffusion are formed; and

a combining unit that overlays and combines the second chip manufactured by the manufacturing unit on the first chip.

(16)

The manufacturing apparatus according to (15), wherein the combining unit combines the first chip and the second chip by attaching a wiring within the pixel of the first chip and a wiring of the second chip with respect to corresponding circuits for every pixel or for every plurality of pixels.

(17)

The manufacturing apparatus according to (15) or (16), further including:

a third chip manufacturing unit that manufactures a third chip in which a logic circuit including a transistor for an input section or an output section of the pixel is formed; and

a third chip combining unit that combines the third chip manufactured by the third chip manufacturing unit with the second chip combined with the first chip by the combining unit.

(18)

A manufacturing method that manufactures an image sensor, the manufacturing method including:

forming a channel portion of a readout transistor that constitutes a pixel of the image sensor, by a channel forming unit; and

forming a floating diffusion so that the floating diffusion and the formed channel portion is overlaid with each other at least partly, by a floating diffusion forming unit.

(19)

An imaging apparatus including:

an image sensor formed so that a channel portion of a readout transistor that constitutes a pixel and a floating diffusion are overlaid with each other at least partly; and

an image processing unit that executes image processing on an image of an object obtained in the image sensor.

(20)

The imaging apparatus according to (19), wherein the floating diffusion and the channel portion of the image sensor are formed in a form of a column on a surface of a photodiode that constitutes the pixel.

### REFERENCE SIGNS LIST

100 image sensor, 111 photodiode, 112 pixel isolation region, 121 N region, 122 P+ region, 123 P− layer, 124 N+ layer, 125 P+ layer, 126 insulating film, 127 gate electrode, 128 interlayer insulating film, 129 contact, 130 wiring layer, 131 wiring, 200 manufacturing apparatus, 201 controlling unit, 202 manufacturing unit, 231 PD forming unit, 232 pixel isolation region forming unit, 233 P− layer forming unit, 234 N+ layer forming unit, 235 P+ layer forming unit, 236 insulating film forming unit, 237 gate electrode forming unit, 238 interlayer insulating film forming unit, 239 contact forming unit, 240 wiring layer forming unit, 300 image sensor, 301 CIS, 302 Logic 1, 303 Logic 2, 400 manufacturing apparatus, 401 controlling unit, 402 manufacturing unit, 431 CIS manufacturing unit, 432 LOGIC 1 manufacturing unit, 433 LOGIC 1 combining unit, 434 LOGIC 2 manufacturing unit, 435 LOGIC 2 combining unit, 436 filter forming unit, 437 collecting lens forming unit, 500 image sensor, 523 N+ layer, 524 P+ layer, 525 P− layer, 600 manufacturing apparatus, 601 controlling unit, 602 manufacturing unit, 633 N+ layer forming unit, 634 P+ layer forming unit, 635 P− layer forming unit, 700 image sensor, 711 FD/TG portion, 712 TR portion, 721 P+ layer, 722 P− layer, 723 gate electrode, 724 contact, 725 wiring, 741 selector, 742 amplifier, 743 reset, 744 GND, 800 manufacturing apparatus, 801 controlling unit, 802 manufacturing unit, 833 P− layer forming unit, 834 N+ layer forming unit, 835 transistor forming unit, 836 P+ layer forming unit, 838 gate electrode forming unit, 840 contact forming unit, 841 wiring layer forming unit, 900 imaging apparatus, 912 CMOS sensor.

1. An image sensor comprising:
a channel portion of a readout transistor that constitutes a pixel; and
a floating diffusion,
wherein the channel portion and the floating diffusion are formed so as to be overlaid with each other at least partly.

2. The image sensor according to claim 1, wherein the channel portion and the floating diffusion are partly or entirely exposed outside a photodiode that constitutes the pixel.

3. The image sensor according to claim 1, wherein the channel portion and the floating diffusion are formed in a form of a column on a surface of a photodiode that constitutes the pixel.

4. The image sensor according to claim 1, wherein the channel portion and the floating diffusion are formed within a region of a photodiode that constitutes a single pixel.

5. The image sensor according to claim 1, wherein the channel portion and the floating diffusion are shared by a plurality of pixels.

6. The image sensor according to claim 1, wherein a gate electrode of the readout transistor is formed so as to partly or entirely surround side surfaces of the channel portion and the floating diffusion.

7. The image sensor according to claim 1, further comprising:
a first chip in which the readout transistor, the floating diffusion, and a photodiode that constitutes the pixel are formed; and
a second chip in which a transistor for amplification, a transistor for selection, and a transistor for reset that constitute the pixel are formed,
wherein the first chip and the second chip are overlaid and combined with each other.

8. The image sensor according to claim 7, wherein the first chip and the second chip are combined so that a wiring within the pixel of the first chip and a wiring of the second chip are attached, with respect to corresponding circuits for every pixel or for every plurality of pixels.

9. The image sensor according to claim 7, wherein a third chip in which a logic circuit including a transistor of an output section or an input section of the pixel is further overlaid and combined with the second chip combined with the first chip.

10. The image sensor according to claim 1, wherein a P− layer of a channel portion of at least one of a transistor for amplification, a transistor for selection, and a transistor for reset that constitute the pixel is formed so as to be piled on a P+ layer.

11. A manufacturing apparatus that manufactures an image sensor, the manufacturing apparatus comprising:
a channel forming unit that forms a channel portion of a readout transistor that constitutes a pixel of the image sensor; and
a floating diffusion forming unit that forms a floating diffusion so that the floating diffusion and the channel portion formed by the channel forming unit is overlaid with each other at least partly.

12. The manufacturing apparatus according to claim 11, further comprising
a photodiode forming unit that forms a photodiode,
wherein the channel forming unit forms the channel portion on a surface of the photodiode formed by the photodiode forming unit, and
wherein the floating diffusion forming unit forms the floating diffusion so that the floating diffusion is overlaid to the channel portion formed on the surface of the photodiode.

13. The manufacturing apparatus according to claim 12,
wherein the floating diffusion forming unit forms the floating diffusion over the surface of the photodiode formed by the photodiode forming unit, and
wherein the channel forming unit forms the channel portion inside the photodiode so that the channel portion is overlaid to the floating diffusion formed by the floating diffusion forming unit.

14. The manufacturing apparatus according to claim 11, further comprising
a transistor forming unit that forms at least one of a transistor for amplification, a transistor for selection, and a transistor for reset that constitute the pixel is formed so that a P− layer of each channel portion is piled on a P+ layer.

15. The manufacturing apparatus according to claim 11, further comprising:
a manufacturing unit that manufactures a second chip in which a transistor for amplification, a transistor for selection, and a transistor for reset that constitute the pixel are formed, as a chip different from a first chip in which the readout transistor and the floating diffusion are formed; and
a combining unit that overlays and combines the second chip manufactured by the manufacturing unit on the first chip.

16. The manufacturing apparatus according to claim 15, wherein the combining unit combines the first chip and the second chip by attaching a wiring within the pixel of the first chip and a wiring of the second chip with respect to corresponding circuits for every pixel or for every plurality of pixels.

17. The manufacturing apparatus according to claim 15, further comprising:
a third chip manufacturing unit that manufactures a third chip in which a logic circuit including a transistor for an input section or an output section of the pixel is formed; and
a third chip combining unit that combines the third chip manufactured by the third chip manufacturing unit with the second chip combined with the first chip by the combining unit.

18. A manufacturing method that manufactures an image sensor, the manufacturing method comprising:
forming a channel portion of a readout transistor that constitutes a pixel of the image sensor, by a channel forming unit; and
forming a floating diffusion so that the floating diffusion and the formed channel portion is overlaid with each other at least partly, by a floating diffusion forming unit.

19. An imaging apparatus comprising:
an image sensor formed so that a channel portion of a readout transistor that constitutes a pixel and a floating diffusion are overlaid with each other at least partly; and
an image processing unit that executes image processing on an image of an object obtained in the image sensor.

20. The imaging apparatus according to claim 19, wherein the floating diffusion and the channel portion of the image sensor are formed in a form of a column on a surface of a photodiode that constitutes the pixel.
